(19) United States
(12) Patent Application Publication
(10) Pub. No.: US 2011/0062539 A1
(43) Pub. Date: Mar. 17, 2011

(54) SEMICONDUCTOR DEVICE AND METHOD OF MANUFACTURING THE SAME

(75) Inventors: Ryoji MATSUDA, Kanagawa (JP); Motoi Ashida, Kanagawa (JP); Shuichi Ueno, Kanagawa (JP); Shoichi Fukui, Kanagawa (JP); Shinya Hirano, Kanagawa (JP); Seiji Muranaka, Kanagawa (JP); Kazuyuki Omori, Kanagawa (JP)

(73) Assignee: RENESAS ELECTRONICS CORPORATION

(21) Appl. No.: 12/885,093

(22) Filed: Sep. 17, 2010

(30) Foreign Application Priority Data
Sep. 17, 2009 (JP) 2009-215385

(51) Int. Cl. H01L 29/82; H01L 21/04

(52) U.S. Cl. 257/422; 438/3; 257/E29.323; 257/E21.04

(57) ABSTRACT

To provide a semiconductor device in which the deterioration of the rewrite property is suppressed. In a memory cell region, magnetoresistive elements in a semiconductor magnetic-storage device are formed in an array shape in a mode that the magnetoresistive elements are arranged at portions where digit lines extending in one direction intersect bit lines extending in the direction approximately orthogonal to the digit lines. The digit line and the bit line have such a wiring structure constituted by covering a copper film to be a wiring main body with a cladding layer. One end side of the magnetoresistive element is electrically coupled to the bit line via a top via formed from a non-magnetic material.

### CROSS-REFERENCE TO RELATED APPLICATION

The disclosure of Japanese Patent Application No. 2009-215385 filed on Sep. 17, 2009 including the specification, drawings and abstract is incorporated herein by reference in its entirety.

### BACKGROUND OF THE INVENTION

The present invention relates to a semiconductor device and a method of manufacturing the same, particularly, to a semiconductor device provided with a magnetoresistive element, and a method of manufacturing the same.

As a form of semiconductor devices, there is an MRAM (Magnetic Random Access Memory) to which a magnetoresistive element referred to as an MTJ (Magnetic Tunnel Junction) is applied. In the MRAM, magnetoresistive elements are formed in an array shape in a mode that the magnetoresistive elements are arranged at portions where digit lines extending in one direction intersect bit lines extending in the direction approximately orthogonal to the digit lines. To each of magnetoresistive elements, two magnetic layers are laminated with a tunnel insulating film lying therebetween.

In these years, in the MRAM, in order to reduce power consumption, a wiring structure including a cladding layer is adopted as the structure of the digit line and the bit line for selectively applying a magnetic field to the magnetoresistive element. The cladding layer has such a function as shielding a magnetic field. Hence, for the digit line lying below the magnetoresistive element, the cladding layer is formed so as to cover the side surface and the lower surface of the digit line, excluding the upper surface of the portion of the digit line positioned directly under the magnetoresistive element. On the other hand, for the bit line positioned above the magnetoresistive element, the cladding layer is formed so as to cover the side surface and the upper surface of the bit line, excluding the lower surface of the portion of the bit line positioned directly on the magnetoresistive element.

Next, an explanation is given about the outline of a method of manufacturing a semiconductor device adopting a wiring structure including such a cladding layer. Over a semiconductor substrate, a first silicon oxide film is formed, and, in the first silicon oxide film, a wiring trench for forming the digit line and extending in one direction is formed. Next, in the wiring trench, the digit line including a barrier metal layer and the cladding layer for covering the side wall and the lower surface of the wiring trench, and a copper wiring for filling up the wiring trench is formed.

Next, so as to cover the digit line, a first silicon nitride film and a second silicon oxide film are sequentially formed over the first silicon oxide film. Next, a local via hole passing through the second silicon oxide film and the first silicon nitride film is formed. So as to fill up the local via hole, a plug of tungsten is formed. Over the second silicon oxide film, an electroconductive layer to be a lower electrode is formed. Next, over portion of the electroconductive layer lying directly on the digit line, the magnetoresistive element is formed.

Next, so as to cover the magnetoresistive element, a second silicon nitride film is formed over the electroconductive layer. By subjecting the second silicon nitride film and the electroconductive layer to a prescribed etching, a lower electrode covered with the second silicon nitride film is formed. Next, so as to cover the second silicon nitride film, a third silicon oxide film is formed over the second silicon oxide film. Next, by dual damascene, a top via hole that exposes the upper surface of the magnetoresistive element, and a wiring trench for forming the bit line extending in a direction approximately orthogonal to the direction in which the digit line extends are formed in the third silicon oxide film.

Next, so as to cover the bottom surface and the side wall of the wiring trench, the cladding layer is formed over the third silicon oxide film. Next, the whole surface of the cladding layer is etched to remove the portion of the cladding layer lying in the bottom surface of the wiring trench, while leaving the portion of the cladding layer lying over the side wall of the wiring trench. Next, so as to fill up the wiring trench, a copper film is formed by copper plating. By subjecting the copper film to a chemical mechanical polishing treatment, the portion of the copper film lying over the upper surface of the third silicon oxide film is removed to form the bit line in the wiring trench.

Next, so as to cover the bit line, a third silicon nitride film is formed. Next, over the portion of the third silicon nitride film, the cladding layer is formed. Next, so as to cover the cladding layer, a fourth silicon oxide film is formed. Thus, the main portion of a semiconductor device provided with the magnetoresistive element is formed. Meanwhile, as an example of documents disclosing such a semiconductor device provided with a wiring structure including the cladding layer, there is Patent Document 1 (Japanese Patent Laid-Open No. 2005-303231).

### SUMMARY OF THE INVENTION

Conventional semiconductor devices, however, involve such a problem as described below. As described above, when the bit line is formed, the cladding layer is formed so as to cover the bottom surface and the side wall of the wiring trench. At this time, the cladding layer is also formed over the side wall and the like of the top via hole having an opening at the bottom surface of the wiring trench.

Consequently, when the whole surface of the cladding layer is etched to remove the portion of the cladding layer lying over the bottom surface of the wiring trench while leaving the portion of the cladding layer lying over the side wall of the wiring trench, the portion of the cladding layer formed over the side wall and the like of the top via hole is not removed but left.

This time, the inventors confirmed by evaluations that the portion of the cladding layer remaining over the side wall of the top via hole affects the property of the magnetoresistive element to make it clear that the rewrite property as the semiconductor device deteriorates.

The present invention was achieved in order to solve the above problem. A purpose thereof is to provide a semiconductor device in which the deterioration of the rewrite property is suppressed, and another purpose is to provide a method of manufacturing such a semiconductor device.

A semiconductor device according to the present invention includes a first region, a magnetoresistive element, a first wiring main body, a second wiring main body, a first conductor portion, and a magnetic field-shielding layer. The first region is formed in a main surface of a semiconductor substrate. The magnetoresistive element is formed in the first region. The first wiring main body is formed so as to extend in a first direction directly under the magnetoresistive element with some spacing. The second wiring main body is formed so as to extend in a second direction intersecting the first direction directly on the magnetoresistive element with some spacing. The first conductor portion is formed between the magnetoresistive element and the second wiring main body, which electrically couples the magnetoresistive element and the second wiring main body. The magnetic field-shielding layer is formed in a prescribed position relative to the magnetoresistive element, and shields a magnetic field generated by the current flowing through the first wiring main body and the second wiring main body. The first conductor portion is formed from a non-magnetic material. The magnetic field-shielding layer is formed over the surface of the second wiring main body in a mode that excludes the portion of the second wiring main body facing the magnetoresistive element, and the first conductor portion.

A method of manufacturing a semiconductor device having a first region and a second region in a main surface of a semiconductor substrate according to the present invention includes the steps below. Over the main surface of the semiconductor substrate, a first insulating film is formed. In the first insulating film, a first wiring trench extending in a first direction is formed. In the first wiring trench, a first wiring main body is formed. So as to cover the first wiring main body, a second insulating film is formed over the first insulating film. Over the surface of the second insulating film, a magnetoresistive element is formed. Over the second insulating film, a third insulating film is formed so as to cover the magnetoresistive element. In the third insulating film, a first opening that exposes the magnetoresistive element is formed. Over the third insulating film, a first electroconductive film made of a non-magnetic material is formed so as to fill up the first opening. The portion of the first electroconductive film lying over the upper surface of the third insulating film is removed to form a first conductor portion electrically coupled to the magnetoresistive element by the portion of the first electroconductive film left in the first opening. So as to cover the first conductor portion, a fourth insulating film is formed over the third insulating film. In the fourth insulating film, a second wiring trench extending in a second direction intersecting the first direction is formed so as to expose the first conductor portion at the bottom surface thereof. In a mode that excludes the bottom surface of the second wiring trench, a magnetic field-shielding layer that shields a magnetic field is formed over the side wall of the second wiring trench. In the second wiring trench, a second wiring main body electrically coupled to the magnetoresistive element via the first conductor portion is formed.

In the semiconductor device according to the present invention, the first conductor portion electrically coupling the magnetoresistive element and the second wiring main body is formed from a non-magnetic material, and the magnetic field-shielding layer is formed over a prescribed surface of the second wiring main body in a mode that excludes the portion of the second wiring main body facing to the magnetoresistive element and the first conductor portion, and thus, it is possible to selectively apply the magnetic field generated by flowing a prescribed current through the first wiring main body and the second wiring main body to the magnetoresistive element without the influence of the first conductor portion, and to surely prevent the deterioration of a rewrite property as the semiconductor device.

In the method of manufacturing a semiconductor device according to the present invention, the first conductor portion electrically coupling the magnetoresistive element and the second wiring main body is formed from a non-magnetic material, and the magnetic field-shielding layer shielding a magnetic field is formed over the side wall of the second wiring trench in a mode that excludes the bottom surface of the second wiring trench, and thus, it is possible to manufacture the semiconductor device in which the deterioration of a rewrite property is surely prevented by selectively applying a magnetic field generated by flowing a prescribed current through the first wiring main body and the second wiring main body to the magnetoresistive element without the influence of the first conductor portion.

### BRIEF DESCRIPTION OF THE DRAWINGS

FIG. 1 is a schematic structural perspective view showing the arrangement relation of the magnetoresistive element, the digit line and the bit line in the memory cell of a semiconductor device according to respective Examples of the present invention;

FIG. 2 is a plan view showing the layout of the memory cell in respective Examples;

FIG. 3 is a cross-sectional view showing the memory cell and the peripheral circuitry in the semiconductor device in respective Examples;

FIG. 4 is a partial cross-sectional perspective view showing a process of manufacturing the memory cell in the semiconductor device according to Example 1 of the present invention;

FIG. 5 is a partial cross-sectional perspective view showing a process performed after the process shown in FIG. 4 in the same Example;

FIG. 6 is a partial cross-sectional perspective view showing a process performed after the process shown in FIG. 5 in the same Example;

FIG. 7 is a partial cross-sectional perspective view showing a process performed after the process shown in FIG. 6 in the same Example;

FIG. 8 is a partial cross-sectional perspective view showing a process performed after the process shown in FIG. 7 in the same Example;

FIG. 9 is a partial cross-sectional perspective view showing a process performed after the process shown in FIG. 8 in the same Example;

FIG. 10 is a partial cross-sectional perspective view showing a process performed after the process shown in FIG. 9 in the same Example;

FIG. 11 is a partial cross-sectional perspective view showing a process performed after the process shown in FIG. 10 in the same Example;

FIG. 12 is a partial cross-sectional perspective view showing a process performed after the process shown in FIG. 11 in the same Example;

FIG. 13 is a partial cross-sectional perspective view showing a process performed after the process shown in FIG. 12 in the same Example;

FIG. 14 is a partial cross-sectional perspective view showing a process performed after the process shown in FIG. 13 in the same Example;

FIG. 15 is a partial cross-sectional perspective view showing a process performed after the process shown in FIG. 14 in the same Example;

FIG. 16 is a partial cross-sectional perspective view showing a process performed after the process shown in FIG. 15 in the same Example;

FIG. 17 is a partial cross-sectional perspective view showing a process performed after the process shown in FIG. 16 in the same Example;

FIG. 18 is a partial cross-sectional perspective view showing a process performed after the process shown in FIG. 17 in the same Example;

FIG. 19 is a partial cross-sectional perspective view showing a process performed after the process shown in FIG. 18 in the same Example;

FIG. 20 is a partial cross-sectional perspective view showing a process performed after the process shown in FIG. 19 in the same Example;

FIG. 21 is a partial cross-sectional perspective view showing a process performed after the process shown in FIG. 20 in the same Example;

FIG. 22 is a partial cross-sectional perspective view along the bit line direction of the memory cell and a partial cross-sectional perspective view along the direction orthogonal to the bit line direction of the memory cell, showing a process performed after the process shown in FIG. 21 in the same Example;

FIG. 23 is a partial cross-sectional perspective view along the bit line direction of the memory cell and a partial cross-sectional perspective view along the direction orthogonal to the bit line direction of the memory cell, showing a process performed after the process shown in FIG. 22 in the same Example;

FIG. 24 is a partial cross-sectional perspective view along the bit line direction of the memory cell and a partial cross-sectional perspective view along a direction orthogonal to the bit line direction of the memory cell, showing a process performed after the process shown in FIG. 23 in the same Example;

FIG. 25 is a partial cross-sectional perspective view along the bit line direction of the memory cell and a partial cross-sectional perspective view along a direction orthogonal to the bit line direction of the memory cell, showing a process performed after the process shown in FIG. 24 in the same Example;

FIG. 26 is a partial cross-sectional perspective view along the bit line direction of the memory cell and a partial cross-sectional perspective view along a direction orthogonal to the bit line direction of the memory cell, showing a process performed after the process shown in FIG. 25 in the same Example;

FIG. 27 is a partial cross-sectional perspective view along the bit line direction of the memory cell and a partial cross-sectional perspective view along a direction orthogonal to the bit line direction of the memory cell, showing a process performed after the process shown in FIG. 26 in the same Example;

FIG. 28 is a partial cross-sectional perspective view showing one process of a method of manufacturing the memory cell in a semiconductor device according to a Comparative Example;

FIG. 29 is a partial cross-sectional perspective view showing a process performed after the process shown in FIG. 28;

FIG. 30 is a partial cross-sectional perspective view showing a process performed after the process shown in FIG. 29;

FIG. 31 is a partial cross-sectional perspective view showing a process performed after the process shown in FIG. 30;

FIG. 32 is a partial cross-sectional perspective view showing a process performed after the process shown in FIG. 31;

FIG. 33 is a partial cross-sectional perspective view showing a process performed after the process shown in FIG. 32;

FIG. 34 is a partial cross-sectional perspective view showing another etching mode in the process shown in FIG. 17 in the Example 1;

FIG. 35 is a partial cross-sectional perspective view showing a process performed after the process shown in FIG. 34 in the same Example;

FIG. 36 is a partial cross-sectional perspective view showing one process of a method of manufacturing the memory cell and the peripheral circuitry in a semiconductor device according to Example 2 of the present invention;

FIG. 37 is a partial cross-sectional perspective view showing a process performed after the process shown in FIG. 36 in the same Example;

FIG. 38 is a partial cross-sectional perspective view showing a process performed after the process shown in FIG. 37 in the same Example;

FIG. 39 is a partial cross-sectional perspective view showing a process performed after the process shown in FIG. 38 in the same Example;

FIG. 40 is a partial cross-sectional perspective view showing a process performed after the process shown in FIG. 39 in the same Example;

FIG. 41 is a partial cross-sectional perspective view showing a process performed after the process shown in FIG. 40 in the same Example;

FIG. 42 is a partial cross-sectional perspective view showing a process performed after the process shown in FIG. 41 in the same Example;

FIG. 43 is a partial cross-sectional perspective view showing a process performed after the process shown in FIG. 42 in the same Example;

FIG. 44 is a partial cross-sectional perspective view showing a process performed after the process shown in FIG. 43 in the same Example;

FIG. 45 is a partial cross-sectional perspective view showing a process performed after the process shown in FIG. 44 in the same Example;

FIG. 46 is a partial cross-sectional perspective view of the memory cell showing a process performed after the process shown in FIG. 45 in the same Example;

FIG. 47 is a partial cross-sectional perspective view showing a process performed after the process shown in FIG. 46 in the same Example;

FIG. 48 is a partial cross-sectional perspective view showing a process performed after the process shown in FIG. 47 in the same Example;

FIG. 49 is a partial cross-sectional perspective view along the bit line direction of the peripheral circuitry and a partial cross-sectional perspective view along the direction orthogonal to the bit line of the peripheral circuitry in the process shown in FIG. 48 in the same Example;

FIG. 50 is a partial cross-sectional perspective view of the memory cell showing a process performed after the process shown in FIG. 48 in the same Example;

FIG. 51 is a partial cross-sectional perspective view showing a process performed after the process shown in FIG. 50 in the same Example;

FIG. 52 is a partial cross-sectional perspective view showing a process performed after the process shown in FIG. 51 in the same Example;

FIG. 53 is a partial cross-sectional perspective view along the bit line direction of the peripheral circuitry and a partial cross-sectional perspective view along a direction orthogonal to the bit line direction of the peripheral circuitry in the process shown in FIG. 52 in the same Example;

FIG. 54 is a partial cross-sectional perspective view showing one process of a method of manufacturing the memory cell and the peripheral circuitry of a semiconductor device according to Comparative Example;

FIG. 55 is a partial cross-sectional perspective view showing a process performed after the process shown in FIG. 54;

FIG. 56 is a partial cross-sectional perspective view showing a process performed after the process shown in FIG. 55;

FIG. 57 is a partial cross-sectional perspective view showing a process performed after the process shown in FIG. 56;

FIG. 58 is a partial cross-sectional perspective view showing a process performed after the process shown in FIG. 57;

FIG. 59 is a partial cross-sectional perspective view showing a process performed after the process shown in FIG. 58;

FIG. 60 is a partial cross-sectional perspective view showing one process of a method of manufacturing the memory cell and the peripheral circuitry in a semiconductor device according to Example 3 of the present invention;

FIG. 61 is a partial cross-sectional perspective view showing a process performed after the process shown in FIG. 60 in the same Example;

FIG. 62 is a partial cross-sectional perspective view showing a process performed after the process shown in FIG. 61 in the same Example;

FIG. 63 is a partial cross-sectional perspective view showing a process performed after the process shown in FIG. 62 in the same Example;

FIG. 64 is a partial cross-sectional perspective view showing a process performed after the process shown in FIG. 63 in the same Example;

FIG. 65 is a partial cross-sectional perspective view showing a process performed after the process shown in FIG. 64 in the same Example;

FIG. 66 is a partial cross-sectional perspective view along the bit line direction of the memory cell and a partial cross-sectional perspective view along the direction orthogonal to the bit line direction of the memory cell showing a process performed after the process shown in FIG. 65 in the same Example;

FIG. 67 is a partial cross-sectional perspective view along the bit line direction of the peripheral circuitry and a partial cross-sectional perspective view along the direction orthogonal to the bit line direction of the peripheral circuitry in the process shown in FIG. 66;

FIG. 68 is a partial cross-sectional perspective view showing one process of a method of manufacturing the memory cell and the peripheral circuitry in a semiconductor device according to Example 4 of the present invention;

FIG. 69 is a partial cross-sectional perspective view showing a process performed after the process shown in FIG. 68 in the same Example;

FIG. 70 is a partial cross-sectional perspective view showing a process performed after the process shown in FIG. 69 in the same Example;

FIG. 71 is a partial cross-sectional perspective view along the bit line direction of the memory cell and a partial cross-sectional perspective view along the direction orthogonal to the bit line direction of the memory cell showing a process performed after the process shown in FIG. 70 in the same Example; and

FIG. 72 is a partial cross-sectional perspective view along the bit line direction of the peripheral circuitry and a partial cross-sectional perspective view along the direction orthogonal to the bit line direction of the peripheral circuitry in the process shown in FIG. 71 in the same Example.

### DETAILED DESCRIPTION OF THE PREFERRED EMBODIMENTS

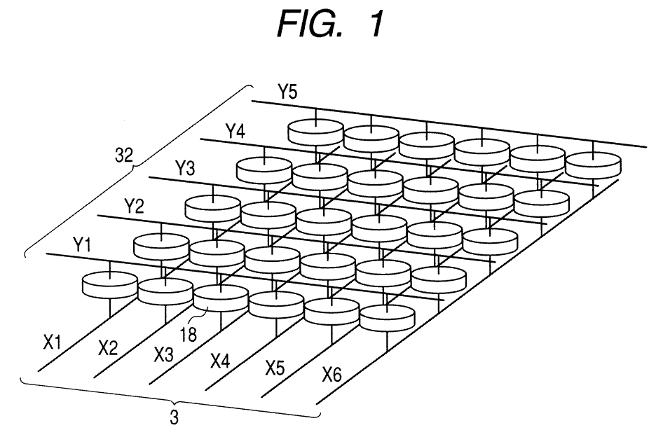

At the beginning, the whole constitution of the semiconductor device is explained. As shown in FIG. 1, magnetoresistive elements 18 in the semiconductor device are formed in an array shape in a mode to be arranged at intersecting portions of digit lines 3 extending in one direction and bit lines 32 extending in the direction approximately orthogonal to the digit lines 3.

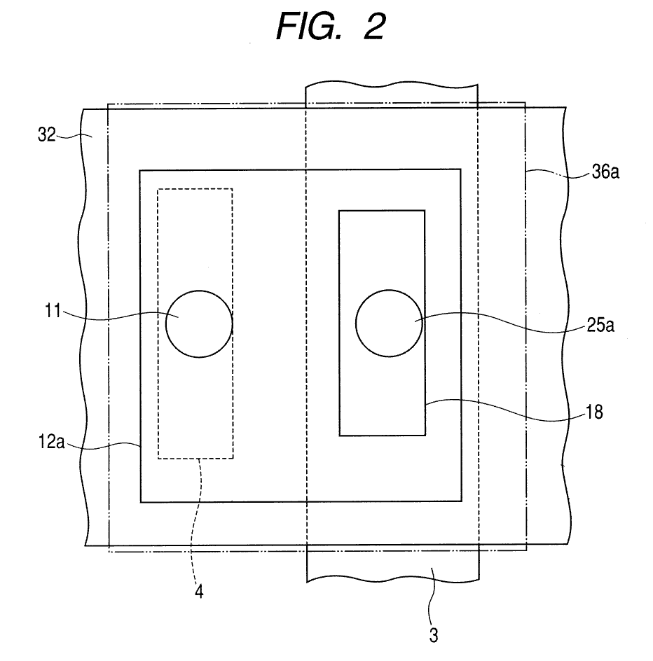

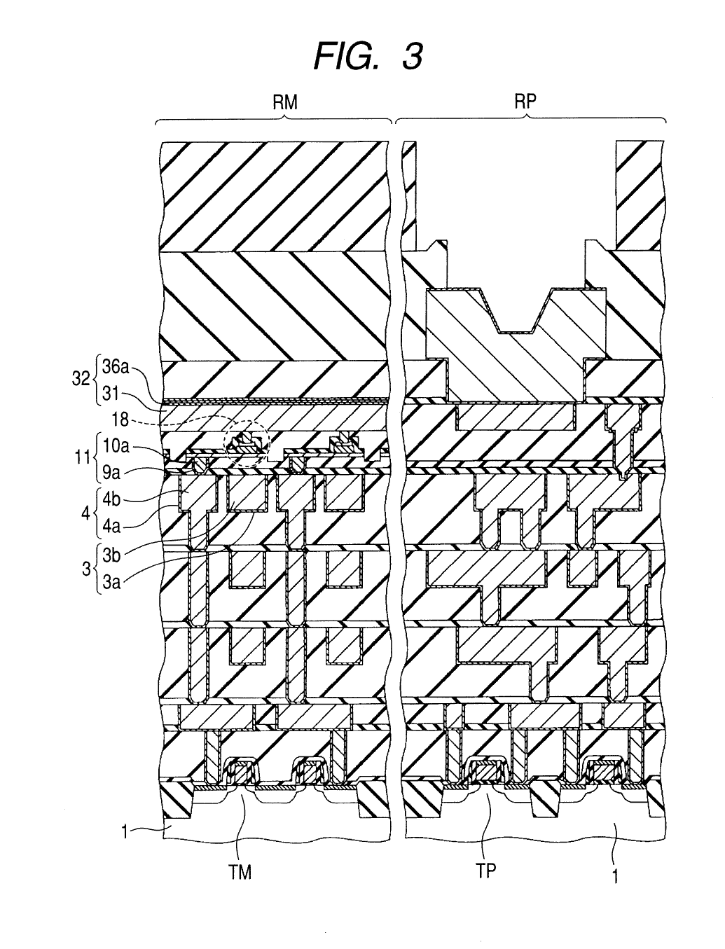

As shown in FIGS. 2 and 3, in a memory cell region RM, a digit line 3 and a bit line 32 are set to have a wiring structure in which copper films 3b and 31 constituting a wiring main body are covered by cladding layers 3a and 36a having the function of shielding a magnetic field. For the digit line 3 positioned below the magnetoresistive element 18, the cladding layer 3a is formed in a mode that covers the bottom surface and the side wall of the copper film 3b so as to prevent the influence of the magnetism on regions other than the magnetoresistive element 18 that lies above.

On the other hand, for the bit line 32 positioned above the magnetoresistive element 18, a cladding layer 36a is formed in a mode that covers the upper surface and the side surface (not shown) of the copper film 31 so as to prevent the influence of the magnetism on regions other than the magnetoresistive element 18 that lies below. Meanwhile, as the cladding layer, for example, a NiFe layer is formed. The cladding layer is to be formed in a mode that laminates a barrier metal of tantalum (Ta) or the like and a cladding layer, but, in the specification, the explanation is given on the assumption that the cladding layer includes the barrier metal, too.

One end side of each magnetoresistive element 18 is electrically coupled to the bit line 32 via a top via 25a. The top via 25a is formed from a non-magnetic material. For the top via 25a, the cladding layer is not formed, as described later. On the other hand, the other end side of the magnetoresistive element 18 is electrically coupled to the drain region of a transistor TM for element selection via a local via 11, a wiring 4 for readout and the like. In a peripheral circuitry region RP, such a semiconductor element as a transistor TP for controlling the operation of the memory cell (the magnetoresistive element), and a wiring or a via that electrically couples semiconductor elements to each other are formed.

To each of magnetoresistive elements, two magnetic layers with a tunnel insulating film interposed therebetween are laminated. Depending on the condition of providing these two magnetic layers with the magnetization in the same direction, or in inverse directions mutually, the resistance value of the magnetoresistive element varies. The magnetization direction of the magnetoresistive element may be changed with a magnetic field that generates by flowing a prescribed current through the bit line and the digit line. In the MRAM, the difference in the resistance value is utilized as the information corresponding to “0” or “1.” Hereinafter, semiconductor devices according to respective Examples will be explained.

### Example 1

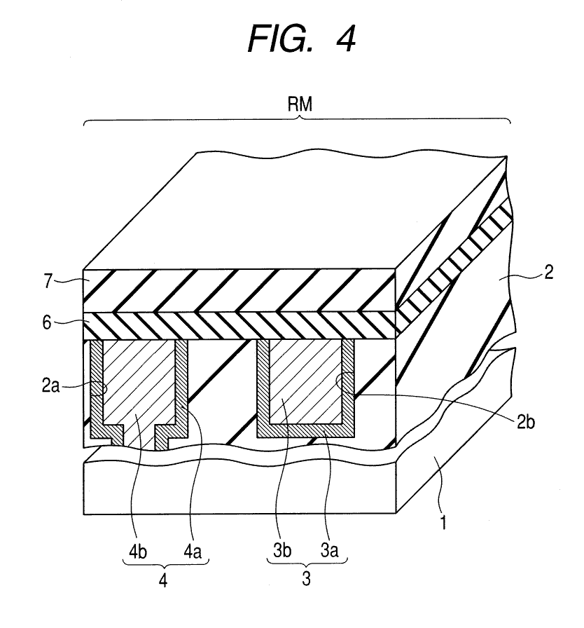

Here, the memory cell formed in the memory cell region of the semiconductor device is explained. After prescribed transistor, wiring, via and the like (see the memory cell region RM in FIG. 3) are formed respectively over the surface of the semiconductor substrate, as shown in FIG. 4, a silicon oxide film 2 is formed. In a prescribed region in the silicon oxide film 2, wiring trenches 2a and 2b are formed. In the wiring trench 2a, a wiring 4 for readout constituted by a cladding layer 4a and a copper film 4b is formed. In the wiring trench 2b, the digit line 3 constituted by the cladding layer 3a and the copper film 3b is formed. Next, over the silicon oxide film 2, a silicon nitride film 6 is formed so as to cover the digit line 3 and the wiring 4 for readout. Over the silicon nitride film 6, a silicon oxide film 7 is formed. Meanwhile, for the purpose of simplifying the drawing, the semiconductor substrate 1 is omitted in drawings showing processes after the above process.

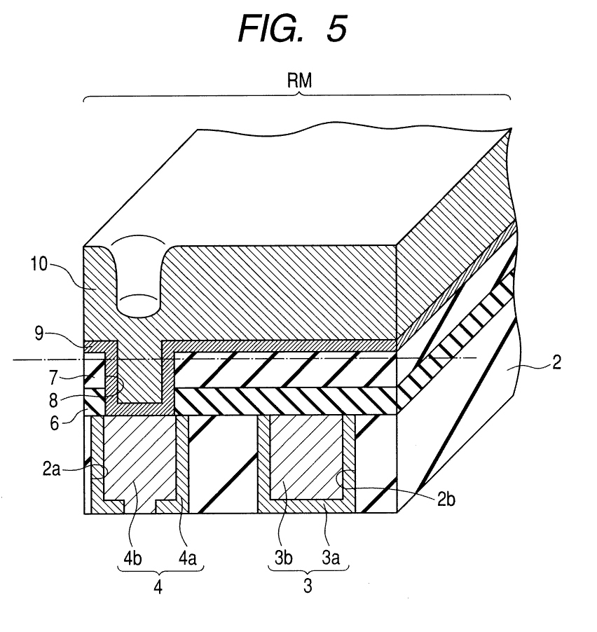

Next, as shown in FIG. 5, a local via hole 8 is formed, which passes through the silicon oxide film 7 and the silicon nitride film 6 and exposes the wiring 4 for readout. So as to cover the bottom surface and the side wall of the local via hole, a barrier metal film 9 is formed over the silicon oxide film 7. Next, over the barrier metal film 9, a tungsten film 10 is formed.

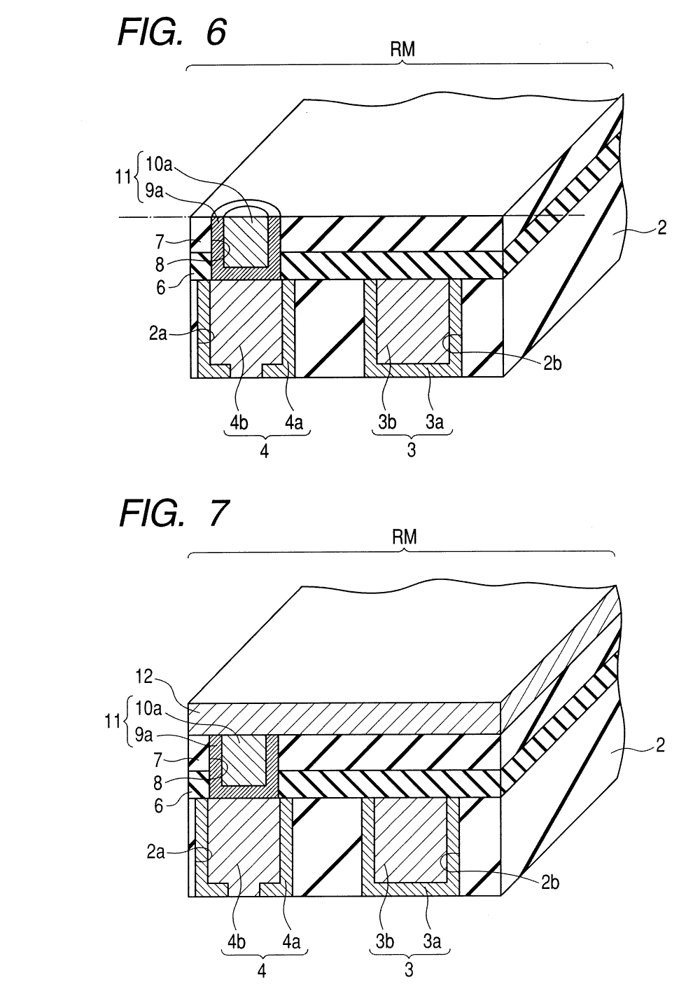

Next, by subjecting the tungsten film 10 and the barrier metal film 9 to a chemical mechanical polishing treatment, the portion of the tungsten film 10 and portion of the barrier metal film 9 lying above the silicon oxide film 7, and a part of the silicon oxide film 7 are removed (refer to the position of the dashed one-dotted line). Thus, as shown in FIG. 6, in the local via hole 8, a local via 11 constituted by a barrier metal film 9a and a tungsten film 10a is formed.

Next, as shown in FIG. 7, over the silicon oxide film 7, a tantalum (Ta) film 12 to be a metal strap is formed. Next, over the tantalum film 12, a prescribed film (not shown) to be a pin layer is formed. As the prescribed film, for example, a laminated film including, for example, platinum (Pt), manganese (Mn), nickel (Ni), ruthenium (Ru), cobalt (Co), iron (Fe) or boron (B) is formed. Next, over the prescribed film to be the pin layer, a tunnel insulating film (not shown) is formed. As the tunnel insulating film, for example, an aluminum oxide (AlOx) film, a magnesium oxide (MgO) film or the like is formed.

Next, over the tunnel insulating film, a prescribed film to be a free layer is formed. As the prescribed film, for example, an alloy film containing at least two metals among nickel (Ni), iron (Fe), cobalt (Co) and boron (B) is formed. Next, over the prescribed film to be the free layer, a prescribed film (not shown) to be a cap layer is formed. As the prescribed film to be the cap layer, for example, a ruthenium (Ru) film is formed. Over the prescribed film to be the cap layer, a tantalum (Ta) film (not shown) is formed.

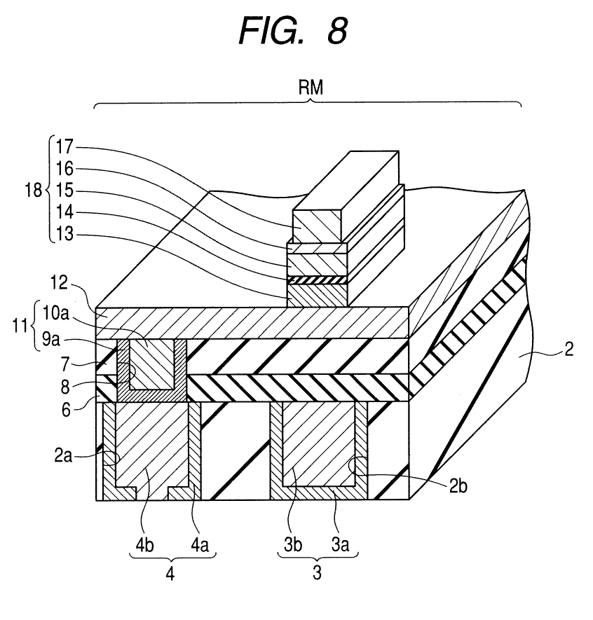

Next, over the tantalum (Ta) film, a resist pattern (not shown) for patterning the magnetoresistive element is formed. Next, using the resist pattern as a mask, the tantalum (Ta) film, the prescribed film to be the cap layer, the prescribed film to be the free layer, the tunnel insulating film and the prescribed film to be the pin layer are etched under prescribed conditions, as shown in FIG. 8, to pattern the pin layer 13, the tunnel insulating film 14, the free layer 15, the cap layer 16 and the tantalum (Ta) film 17, and the magnetoresistive element 18 is formed. In respective manufacturing processes after the formation of the magnetoresistive element 18, in order to protect the magnetoresistive element 18, particularly the tunnel insulating film, various treatments are provided under a temperature of 300° C. or less.

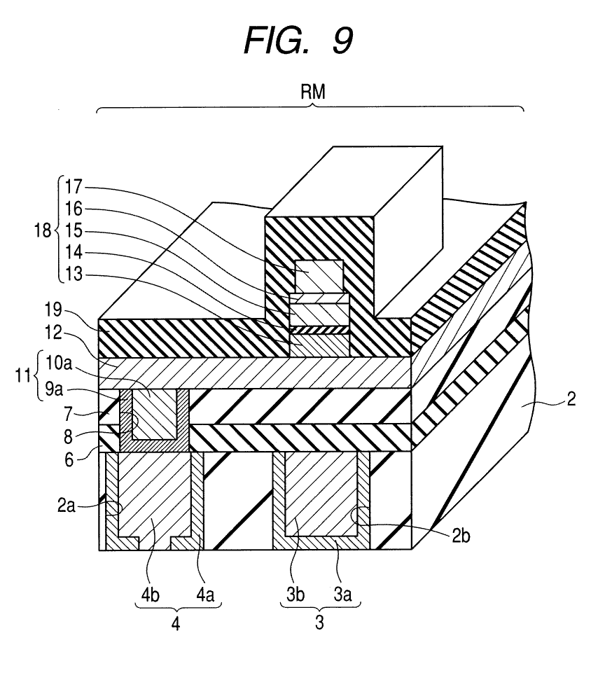

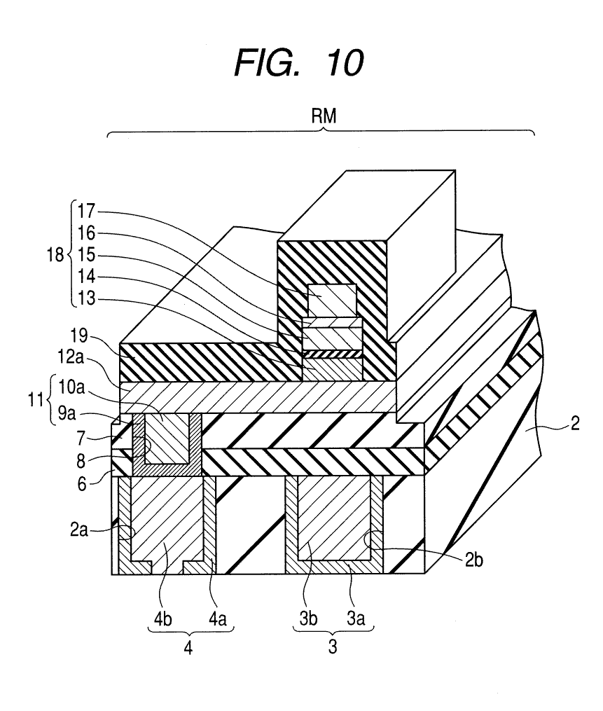

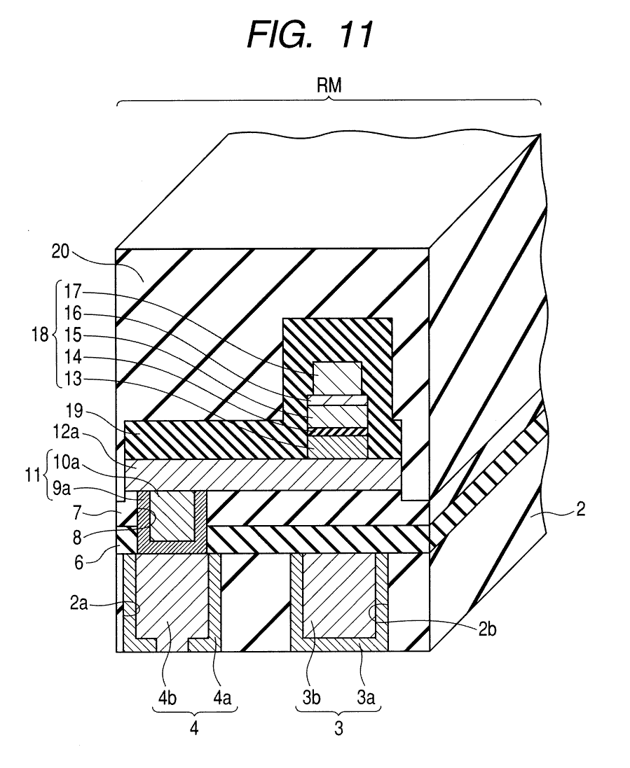

Next, as shown in FIG. 9, over the tantalum (Ta) film 12, a silicon nitride film 19 is formed as a liner film so as to cover the magnetoresistive element 18. Next, over the silicon nitride film 19, a resist pattern (not shown) for patterning the metal strap is formed. Next, using the resist pattern as a mask, the silicon nitride film 19 and the tantalum (Ta) film 12 are etched under prescribed conditions, as shown in FIG. 10, to form a metal strap 12a. Next, a silicon oxide film (not shown) is formed so as to cover the magnetoresistive element 18. By subjecting the silicon oxide film to a chemical mechanical polishing treatment, as shown in FIG. 11, a silicon oxide film 20 having a prescribed thickness is formed.

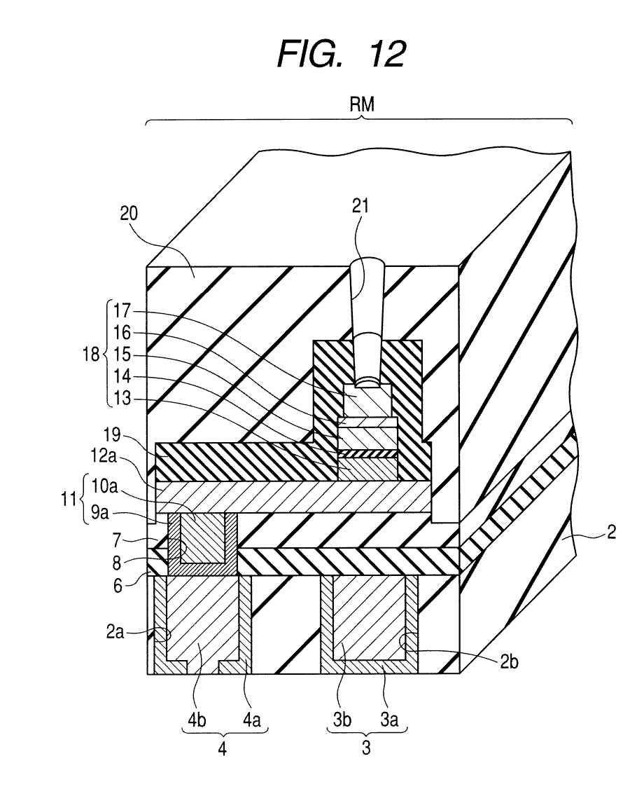

Next, over the silicon oxide film 20, a resist pattern (not shown) for forming a top via hole is formed. Next, using the resist pattern as a mask, the silicon oxide film 20 and the silicon nitride film 19 are etched under prescribed conditions, as shown in FIG. 12, to form a top via hole 21 that exposes the magnetoresistive element 18. Next, so as to cover the side wall of the top via hole 21, a barrier metal layer (not shown) for preventing the diffusion of copper is formed. The barrier metal layer formed here does not include the cladding layer.

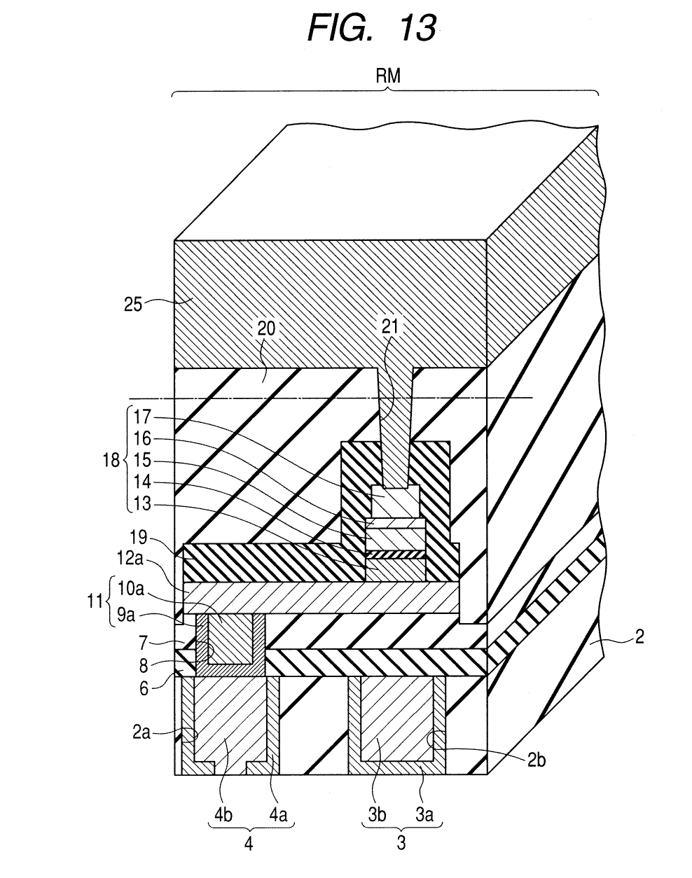

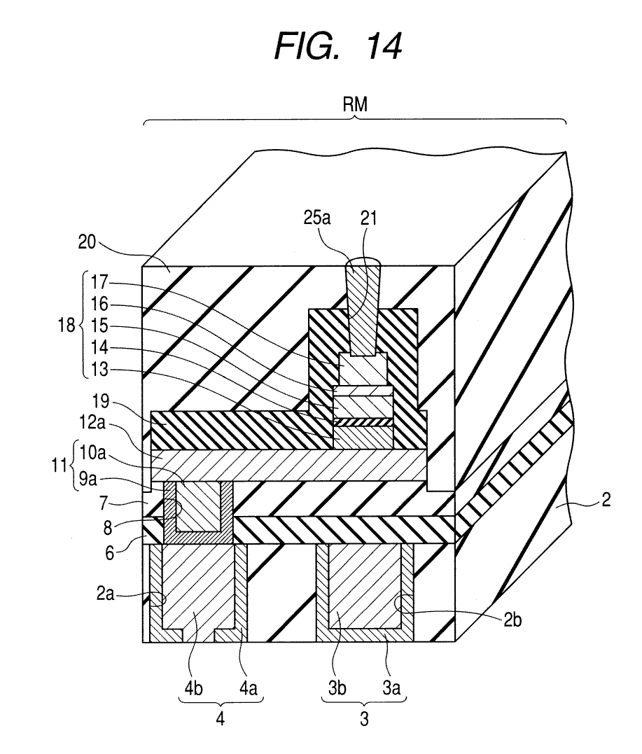

Next, as shown in FIG. 13, so as to fill up the top via hole 21, a copper film 25 is formed over the silicon oxide film 20 as the non-magnetic material by copper plating. Next, by subjecting the copper film 25 to a chemical mechanical polishing treatment, the portion of the copper film 25 lying over the upper surface of the silicon oxide film 20 is removed, and, further, a part of the silicon oxide film 20 is removed (see the position of the dashed one-dotted line). Thus, as shown in FIG. 14, in the top via hole 21, a top via 25a constituted by a non-magnetic material without the cladding layer is formed.

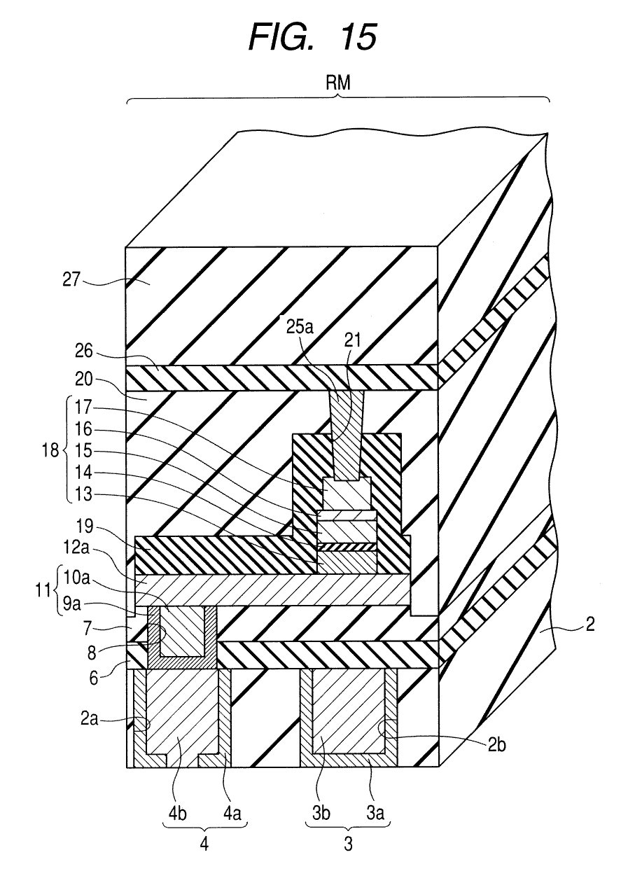

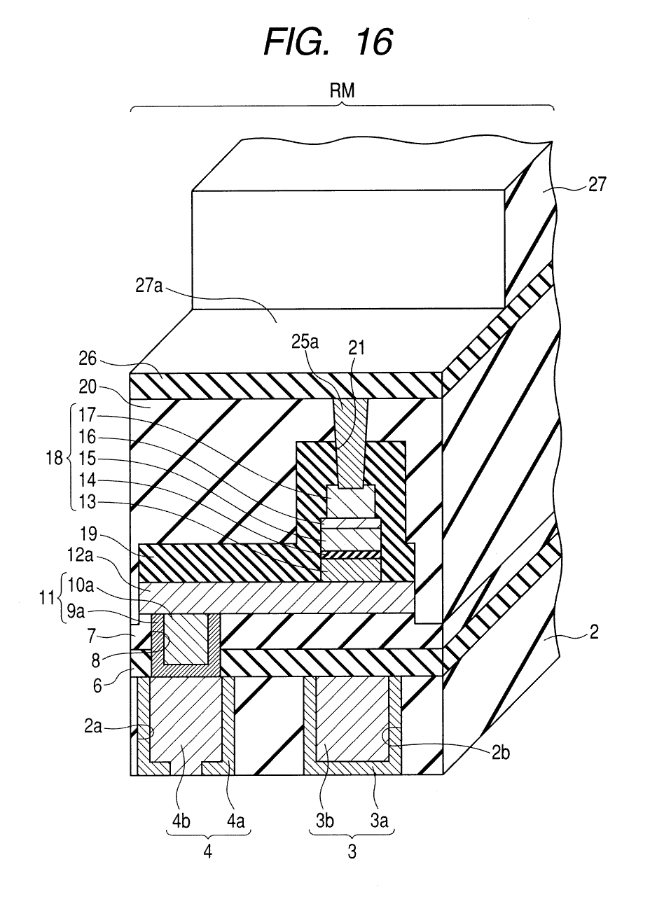

Next, as shown in FIG. 15, over the silicon oxide film 20, a silicon nitride film 26 is formed, and, further, over the silicon nitride film 26, a silicon oxide film 27 is formed. Next, over the silicon oxide film 27, a resist pattern (not shown) for forming a wiring trench for the bit line is formed. Next, using the resist pattern as a mask, the silicon oxide film 27 is etched up to the exposure of the silicon nitride film 26, as shown in FIG. 16, to form an opening 27a.

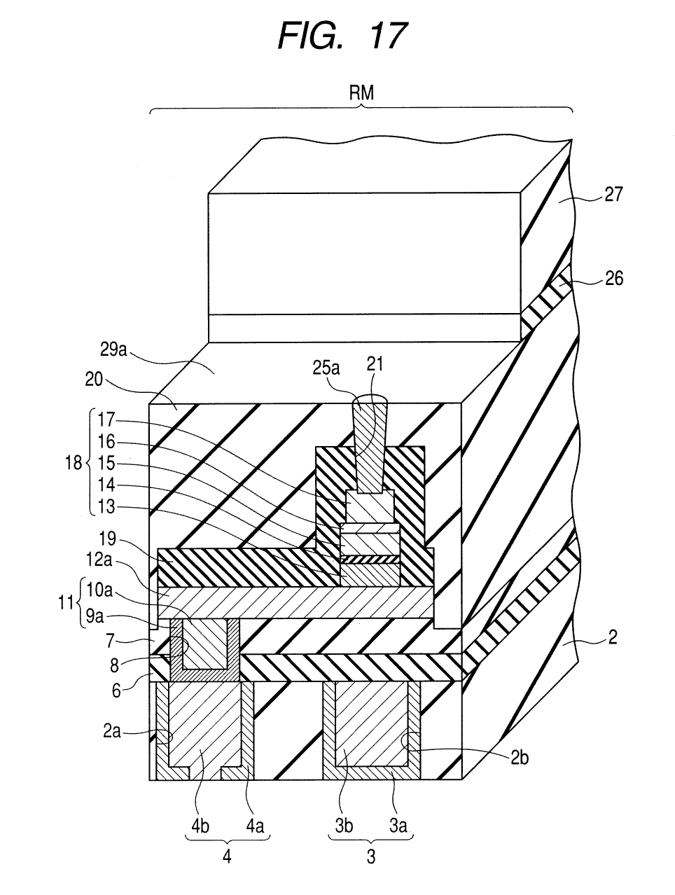

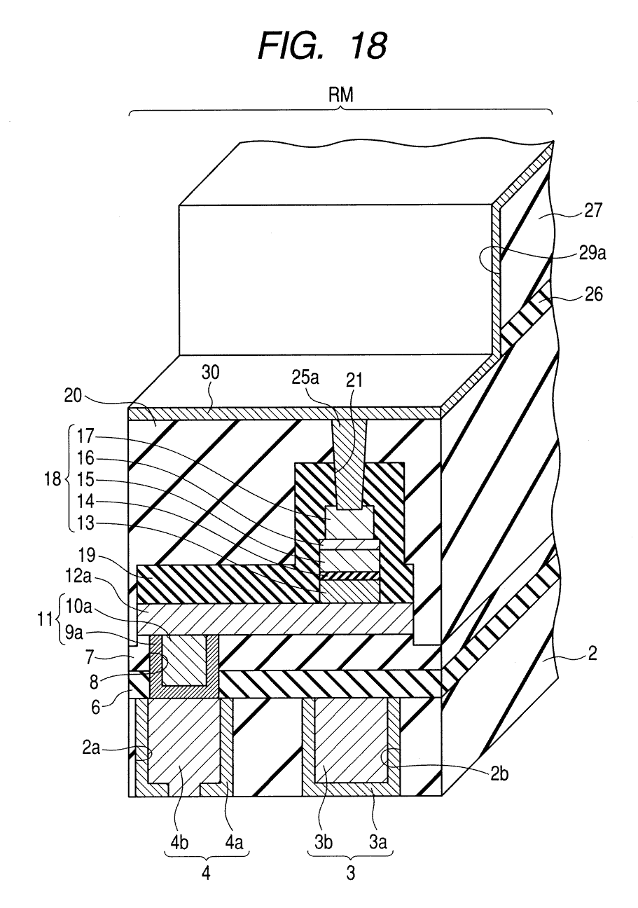

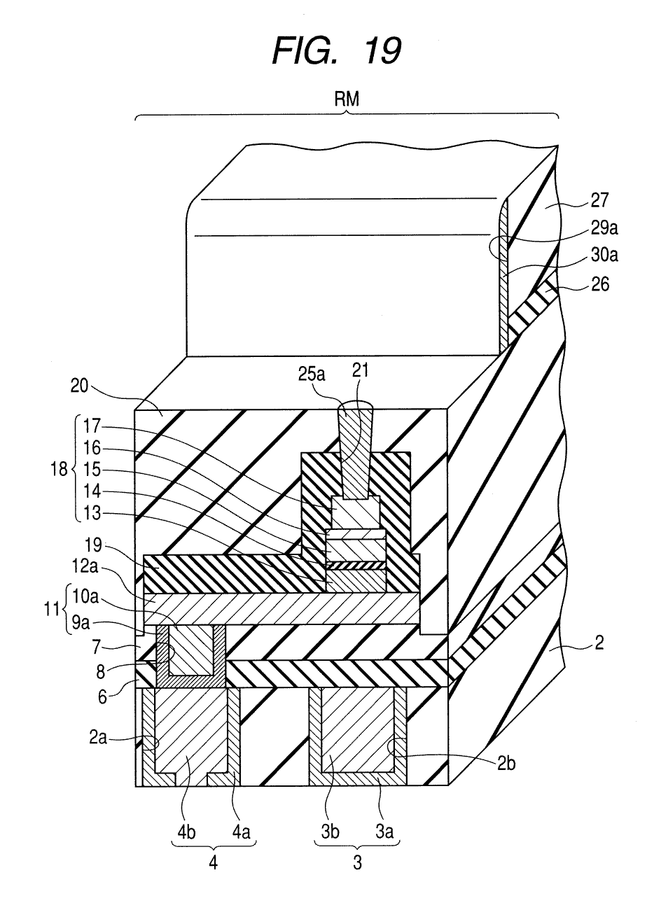

Next, the silicon nitride film 26 exposed at the bottom of the opening 27a is etched, as shown in FIG. 17, to form a wiring trench 29a that exposes the top via 25a. Next, as shown in FIG. 18, so as to cover the bottom surface and the side wall of the wiring trench 29a, a cladding layer 30 is formed. Next, the whole surface of the cladding layer 30 is etched, as shown in FIG. 19, to remove a portion of the cladding layer 30 lying over the bottom surface of the wiring trench 29a, and a portion of the cladding layer 30 lying over the upper surface of the silicon oxide film 27, while leaving a portion of the cladding layer 30 lying over the side wall of the wiring trench 29a (a cladding layer 30a).

Meanwhile, at this time, the cladding layer 30 may be removed in a mode that leaves a part of the barrier metal film in the cladding layer 30 lying over the bottom surface of the wiring trench 29a, and a part of the barrier metal film in the cladding layer 30 lying over the upper surface of the silicon oxide film 27. Further, after that, a barrier metal film (not shown) may be formed so as to cover the bottom surface of the wiring trench 29a, the cladding layer 30a and silicon oxide film 27 formed over the side wall of the wiring trench 29a.

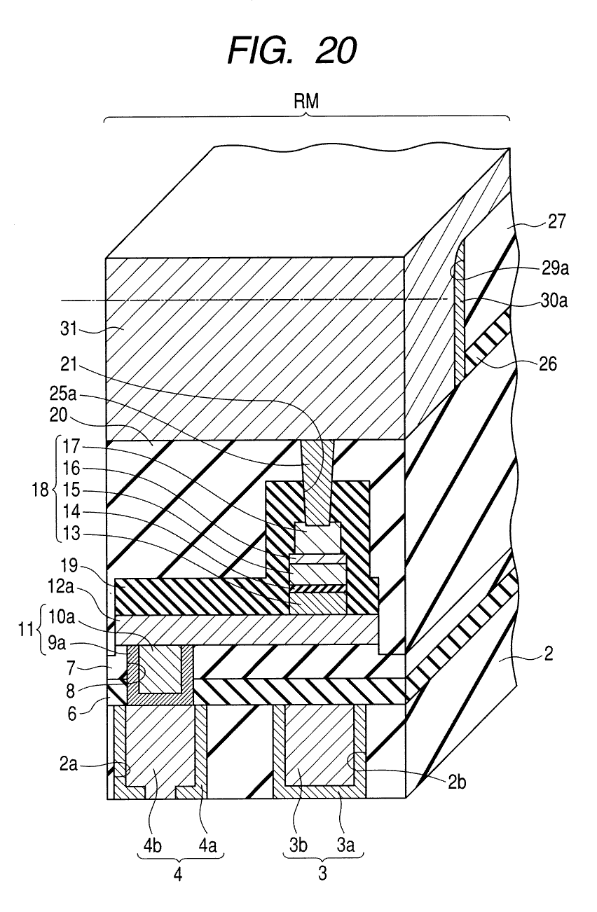

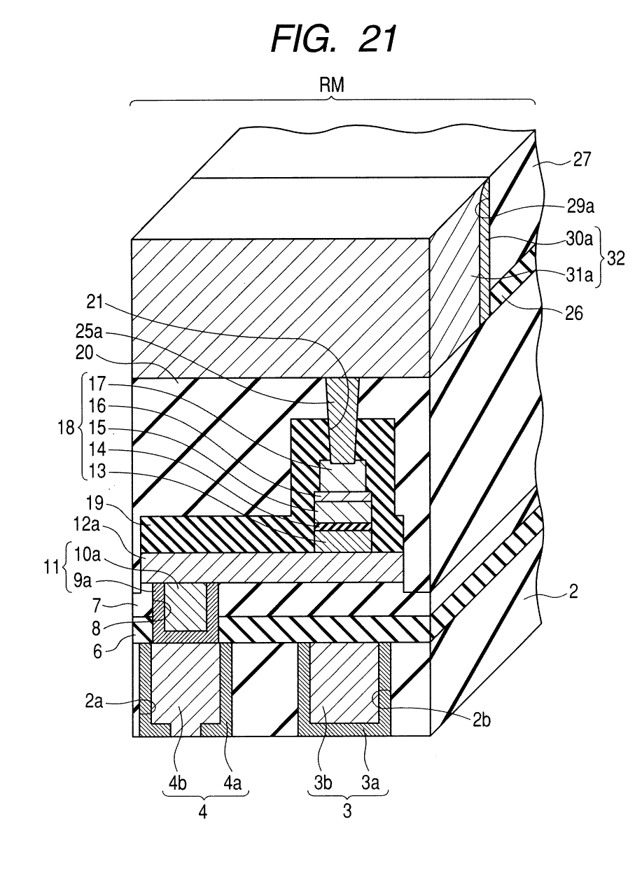

Next, as shown in FIG. 20, so as to fill up the wiring trench 29a, a copper film 31 is formed by copper plating. Next, the copper film 31 is subjected to a chemical mechanical polishing treatment, as shown in FIG. 21, to remove a portion of the copper film 31 lying over the upper surface of the silicon oxide film 27, while leaving a portion of the copper film 31 lying in the wiring trench 29a (a copper film 31a). Thus, in the wiring trench 29a, the bit line 32 constituted by the cladding layer 30a and the copper film 31a is formed.

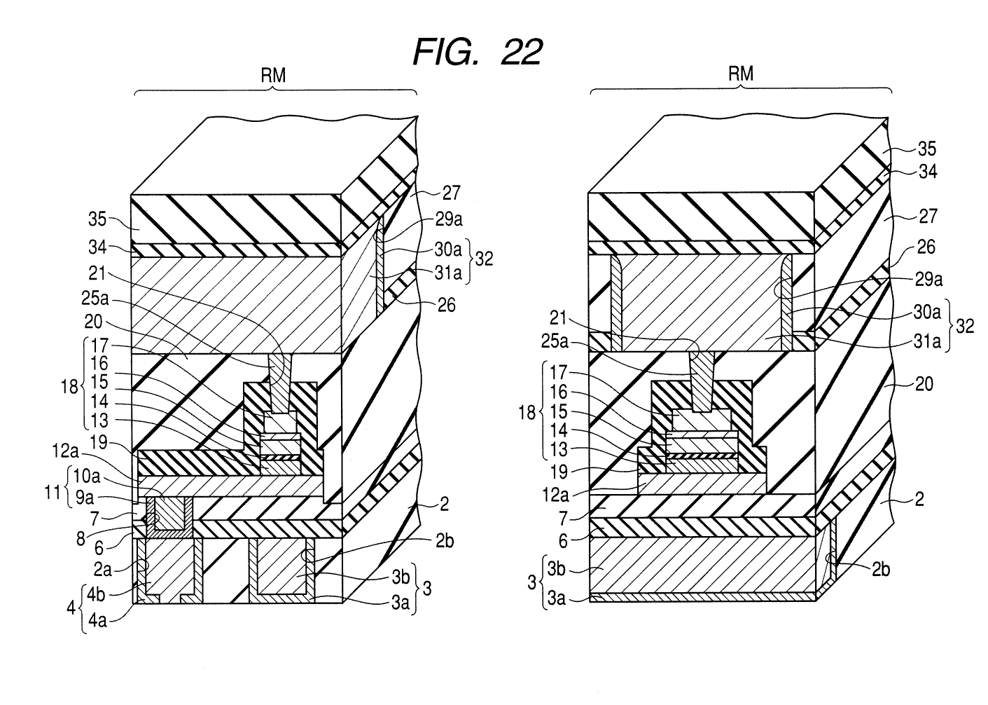

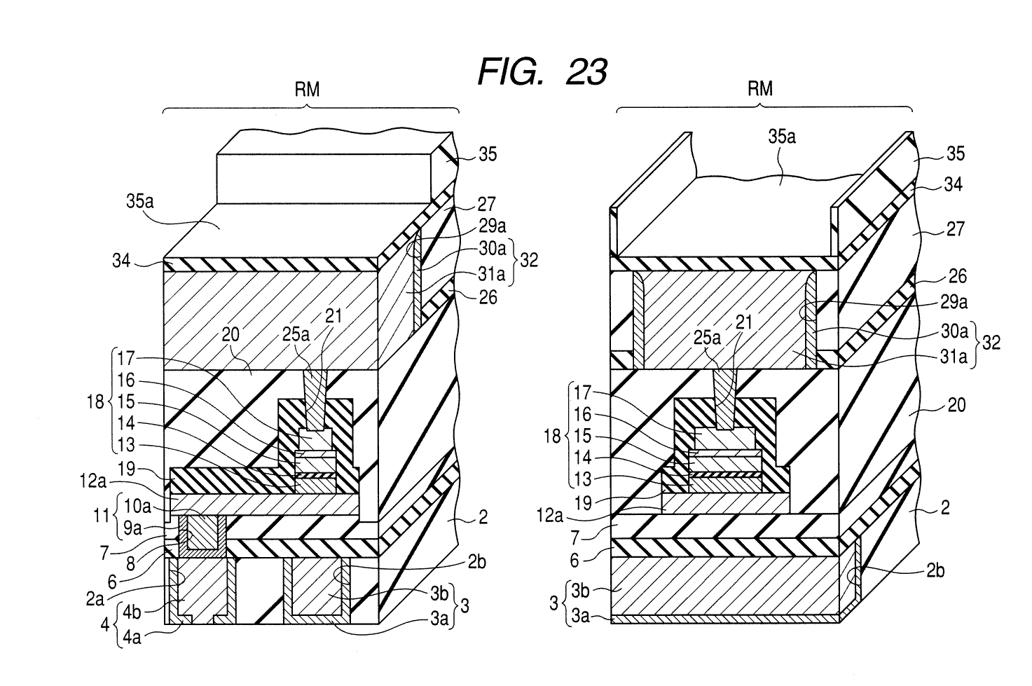

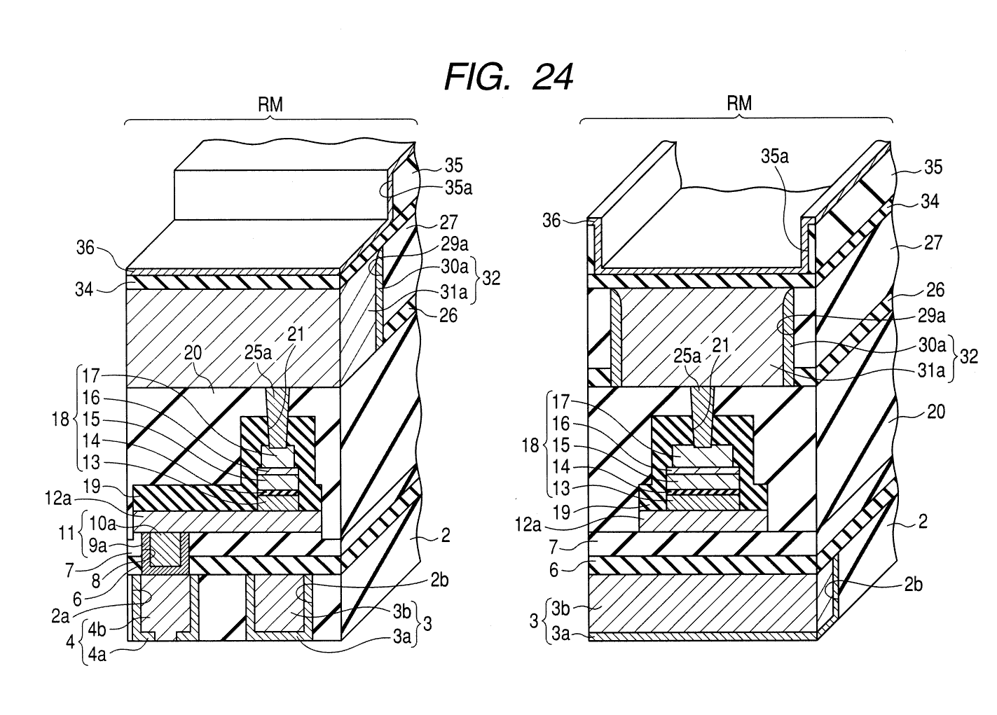

Next, as shown in FIG. 22, so as to cover the bit line 32, a silicon nitride film 34 is formed over the silicon oxide film 27, and, further, over the silicon nitride film 34, a silicon oxide film 35 is formed. Next, over the silicon oxide film 35, a prescribed resist pattern (not shown) for forming a cladding layer covering the bit line 32 from above is formed. Using the resist pattern as a mask, the silicon oxide film 35 is etched up to the exposure of the silicon nitride film 34, as shown in FIG. 23, to form an opening 35a. Next, as shown in FIG. 24, so as to cover the bottom surface and the side wall of the opening 35a, a cladding layer 36 is formed.

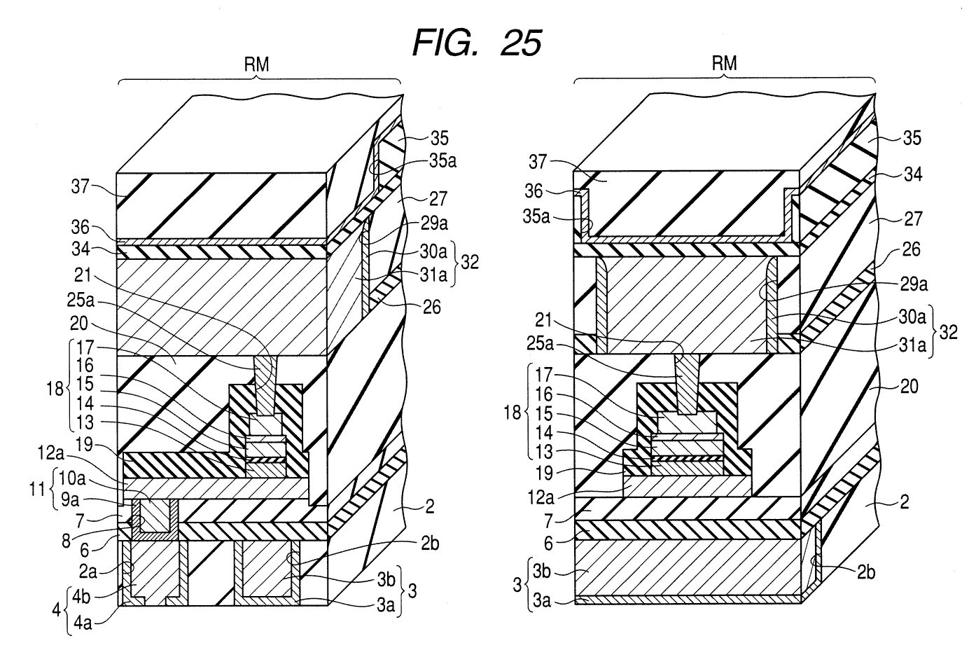

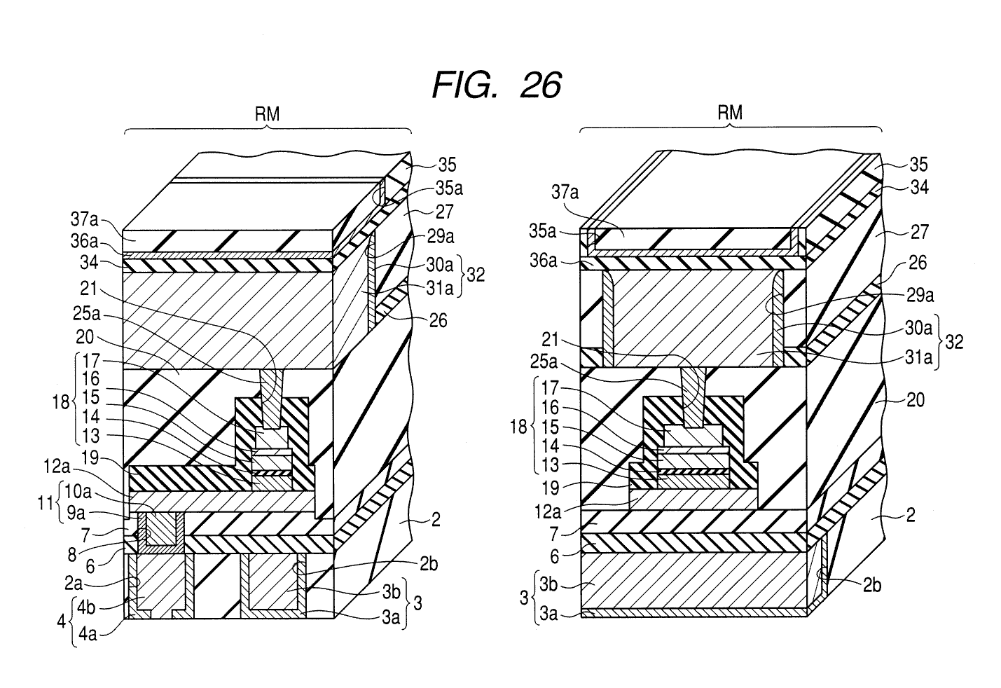

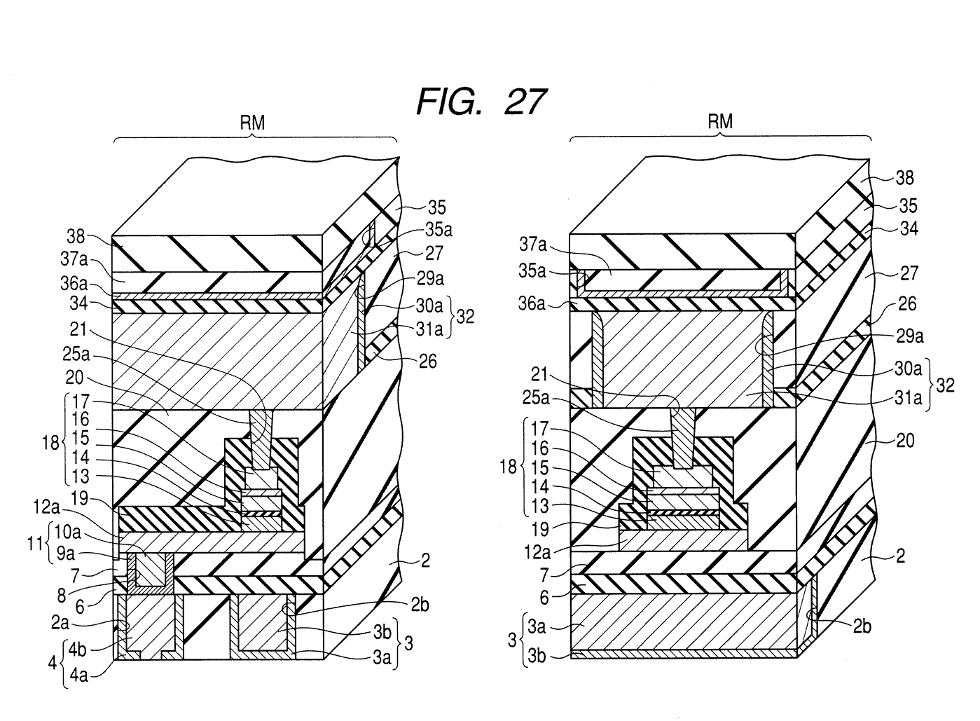

Next, as shown in FIG. 25, over the cladding layer 36, a silicon oxide film 37 is formed so as to fill up the opening 35a. Next, the silicon oxide film 37 and the cladding layer are subjected to a chemical mechanical polishing treatment, as shown in FIG. 26, to remove portions of the cladding layer 36 lying in other regions than the opening 35a, while leaving a portion of the cladding layer 36 lying over the side wall and the bottom surface of the opening 35a (the cladding layer 36a). Thus, the cladding layer 36a covering the bit line 32 from above is formed. Next, as shown in FIG. 27, so as to cover the silicon oxide film 37a and the silicon oxide film 35 left for the opening 35a, a silicon oxide film 38 is formed. Thus, the main portion of the memory cell is formed.

In the aforementioned magnetoresistive element 18 of the semiconductor device, since the top via 25a that electrically couples the magnetoresistive element 18 and the bit line 32 is formed from a copper film (a non-magnetic material) without including the cladding layer, the deterioration of the magnetoresistive element property may be suppressed. This will be explained in relation to Comparative Example.

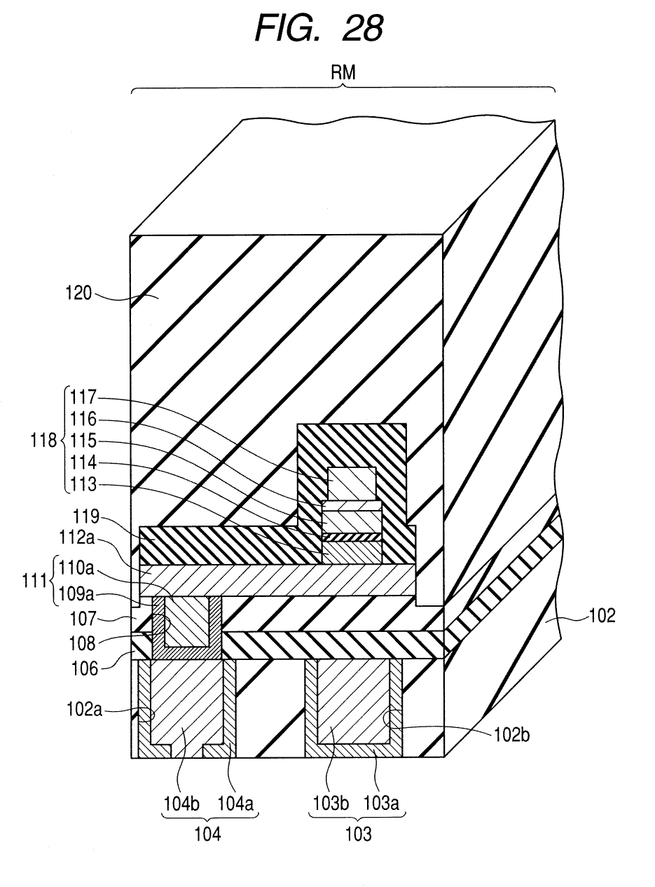

Firstly, a semiconductor device according to Comparative Example will be explained. After forming a prescribed semiconductor element, wiring and the like over a semiconductor substrate, as shown in FIG. 28, in a wiring trench 102a formed in a silicon oxide film 102, a wiring 104 for readout constituted by a cladding layer 104a and a copper film 104b is formed, and in a wiring trench 102b, a digit line 103 constituted by a cladding layer 103a and a copper film 103b is formed. Next, over the silicon oxide film 102, a silicon nitride film 106 and a silicon oxide film 107 are formed, and, in the silicon oxide film 107 and the silicon nitride film 106, a local via hole 108 is formed.

Next, in the local via hole 108, a local via 111 constituted by a barrier metal film 109a and a tungsten film 110a is formed. Next, over the silicon oxide film 107, a film to be a metal strap, respective films to be magnetoresistive elements and the like are formed, which are subjected to a prescribed patterning treatment to form a magnetoresistive element 118 having a pin layer 113, a tunnel insulating film 114, a free layer 115, a cap layer 116 and a tantalum (Ta) film 117. Next, so as to cover the magnetoresistive element 118, a silicon nitride film 119 is formed, and a prescribed patterning is given to form a metal strap 112a. Next, so as to cover the magnetoresistive element 118, a silicon oxide film 120 having a prescribed thickness is formed.

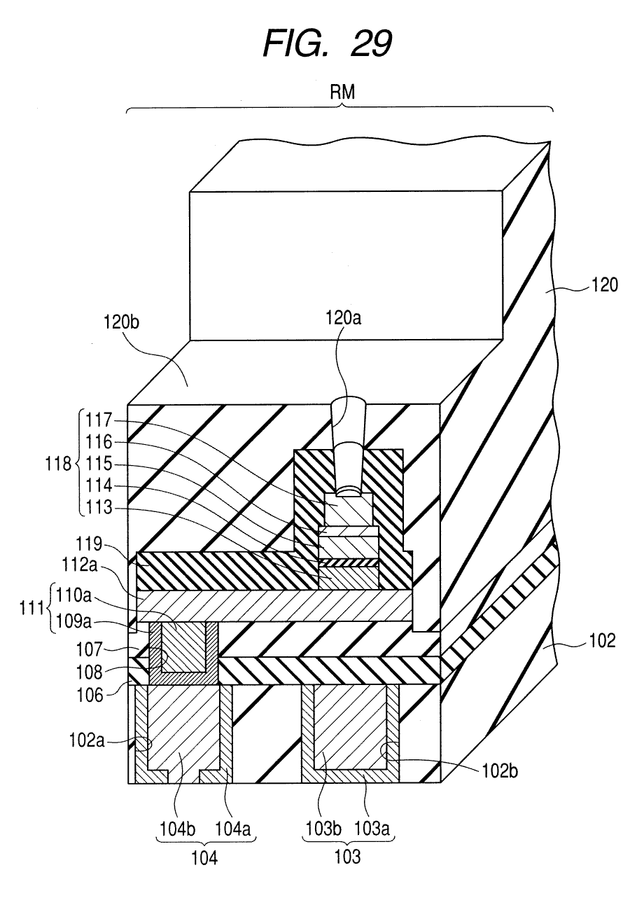

Next, as shown in FIG. 29, using dual damascene, a top via hole 120a that exposes the magnetoresistive element 118 and a wiring trench 120b for the bit line are formed in the silicon oxide film 120. Next, so as to cover the bottom surface and the side wall of the wiring trench 120b, a cladding layer (not shown) is formed over the silicon oxide film 120. At this time, a cladding layer 130 is also formed over the side wall of the top via hole 120a opening at the bottom surface of the wiring trench 120b and the like.

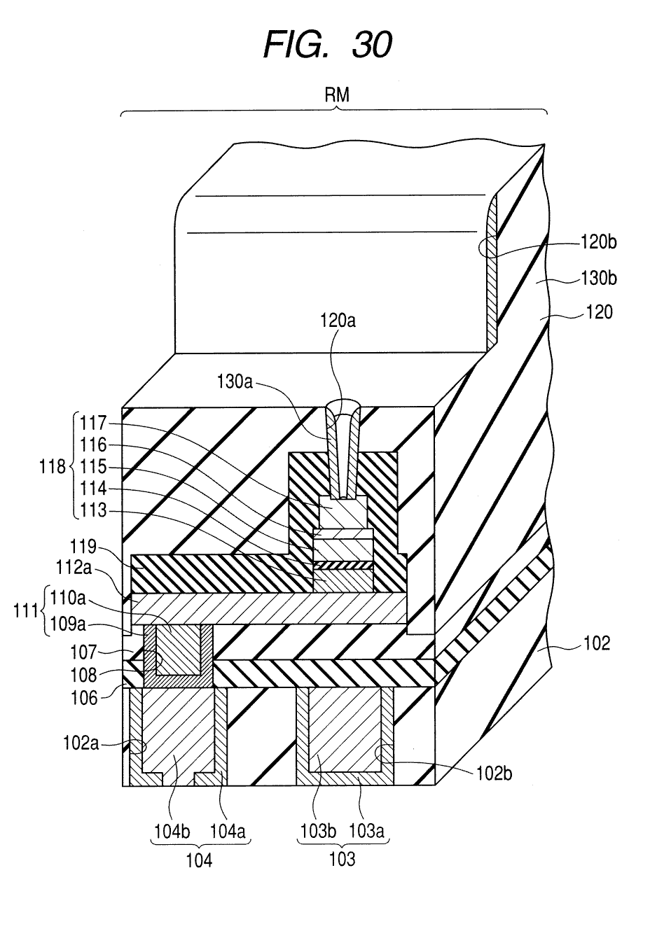

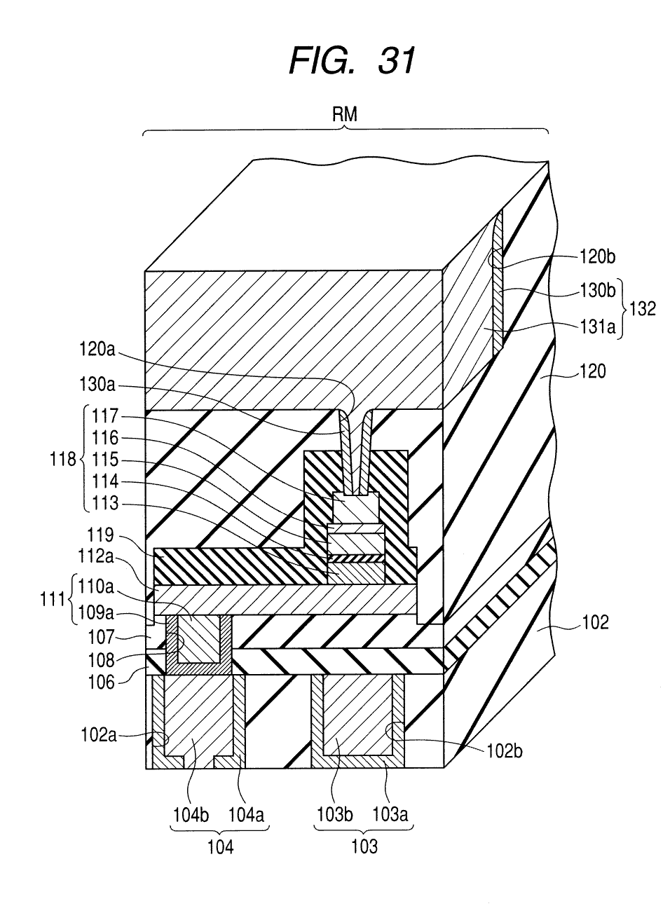

Next, as shown in FIG. 30, the whole surface of the cladding layer 130 is etched to remove the portion of the cladding layer lying over the bottom surface of the wiring trench 120b, and the portion of the cladding layer lying over the upper surface of the silicon oxide film 120, while leaving the portion of the cladding layer lying over the side wall of the wiring trench 120b (a cladding layer 130b). At this time, the portion of the cladding layer formed over the side wall of the top via hole 120a (a cladding layer 130a) is not removed but left. Next, so as to fill up the wiring trench 120b, a copper film (not shown) is formed, and, by subjecting the copper film to a chemical mechanical polishing treatment, as shown in FIG. 31, a bit line 132 constituted by the cladding layer 130b and the copper film 131a is formed in the wiring trench 120b.

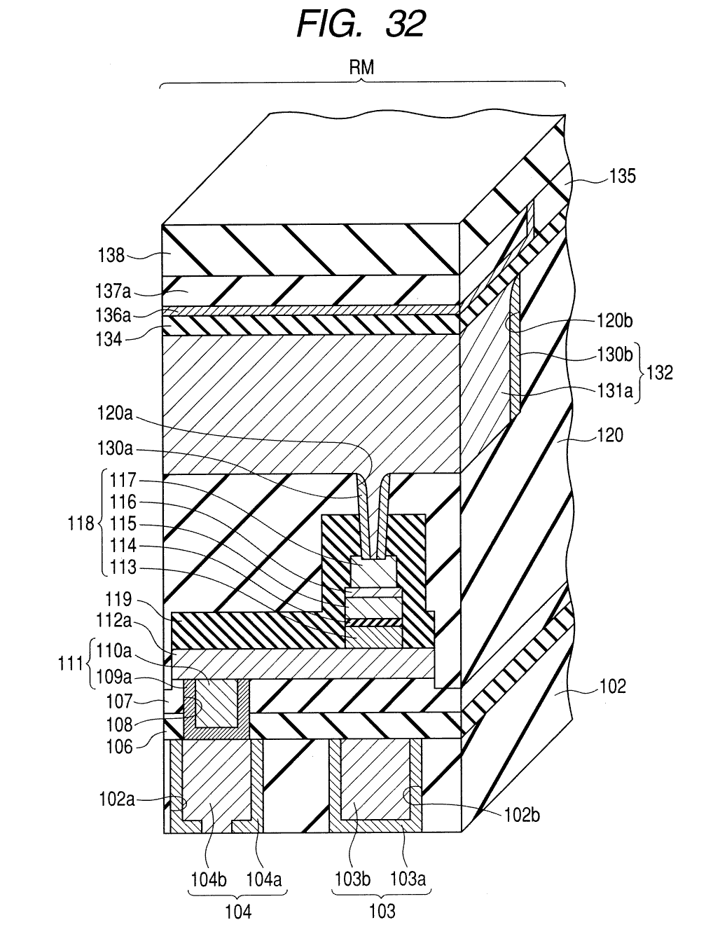

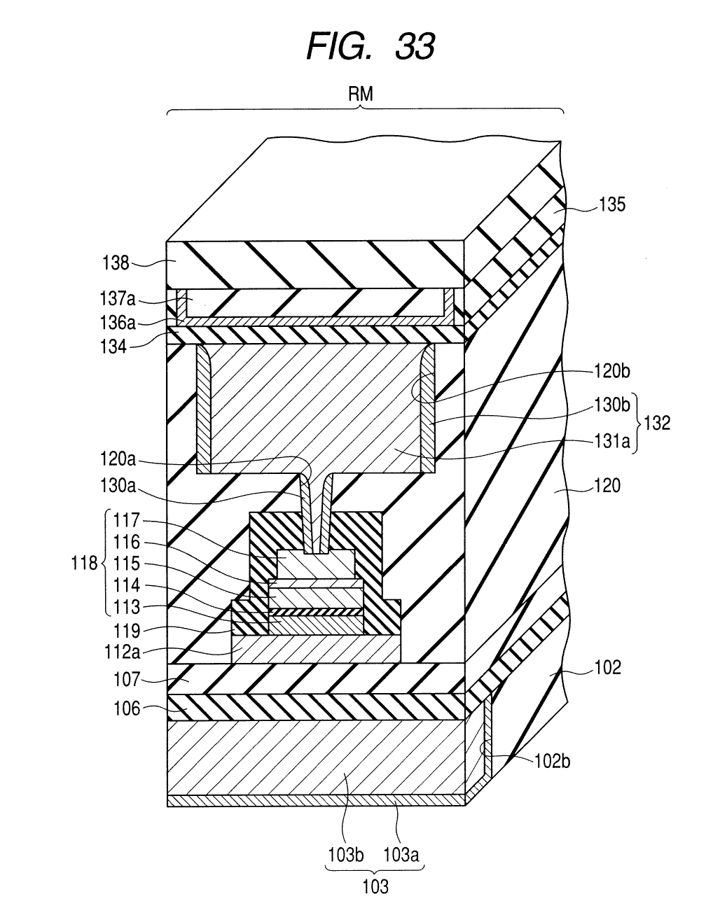

Next, so as to cover the bit line 132, a silicon nitride film 134 (see FIG. 32) and a silicon oxide film 135 (see FIG. 32) are formed, and, in the silicon oxide film, an opening 135a (see FIG. 32) is formed. So as to cover the bottom surface and the side wall of the opening, a cladding layer (not shown) is formed, and, by giving a chemical mechanical polishing treatment, over the side wall and the bottom surface of the opening 135a, a cladding layer 136a (see FIG. 32) is left. After that, as shown in FIGS. 32 and 33, so as to cover the silicon oxide film 137a and the silicon oxide film 135 left for the opening 135a, a silicon oxide film 138 is formed to form the main portion of the memory cell of a semiconductor device according to Comparative Example.

As described above, in the semiconductor device according to Comparative Example, the cladding layer is also formed over the side wall and the like of the top via hole 120a opening at the bottom surface of the wiring trench 120b, when the cladding layer is formed in the wiring trench 120b for the bit line. Consequently, as shown in FIG. 30, even when the whole surface of the cladding layer is etched, in the same manner that the portion of the cladding layer lying over the side wall of the wiring trench 120b (the cladding layer 130b) is left, the portion of the cladding layer lying over the side wall of the top via hole 120a (the cladding layer 130a) is also not removed but left.

When the memory cell is formed in such a state that the cladding layer 130a is left for the top via hole, there is such an anxiety that the magnetic field generated by flowing a prescribed current through the bit line 132 and the digit line 103 is shielded by the cladding layer 130a remaining in the top via hole 120a. Consequently, the magnetic field occasionally does not act effectively on the magnetoresistive element 118 to deteriorate the rewrite property as the semiconductor device. This phenomenon was confirmed for the first time by the present inventors this time.

In contrast, in the aforementioned semiconductor device, each of the top via hole 21 and the wiring trench 29a for the bit line is formed individually by single damascene, and the cladding layer is formed in the wiring trench 29a but is not formed in the top via hole 21. That is, in the top via hole 21, only the barrier metal layer for preventing the diffusion of copper and the copper film 25a are formed, but the cladding layer is not formed.

Consequently, differing from the case of Comparative Example, the magnetic field generated by flowing a prescribed current through the bit line 32 and the digit line 3 is not shielded by the cladding layer 130a remaining in the top via hole 120a, and the generated magnetic field may effectively be acted on the magnetoresistive element 18. Furthermore, due to the cladding layer 30a and the like covering the copper film 31a of the bit line 32, the magnetic field may selectively be acted on the magnetoresistive element 18. As the result, the deterioration of the rewrite property as the semiconductor device may surely be prevented.

Moreover, in the aforementioned semiconductor device, since the top via hole 21 is formed by single damascene, it is possible to set the etching condition when forming the top via hole 21 while paying attention only to forming the top via hole 21, and to achieve the optimization of the etching condition so as to give the smallest etching damage to the magnetoresistive element 18.

Furthermore, in the aforementioned semiconductor device, since the wiring trench 29a for the bit line 32 is formed by single damascene, the optimization of conditions when forming the cladding layer 30a for the bit line 32 may also be achieved easily.

### Modified Example

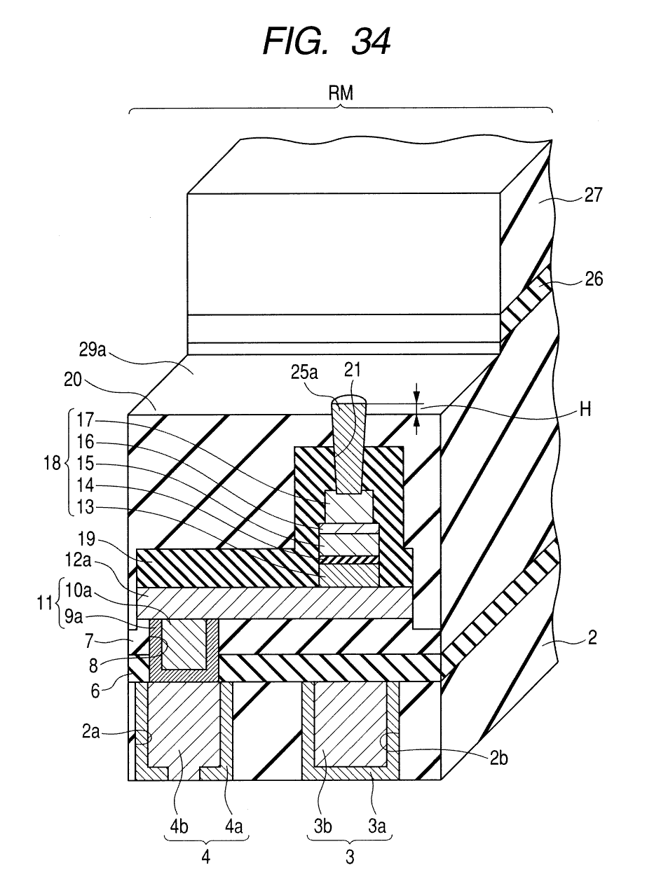

In the aforementioned method of manufacturing the semiconductor device, when forming the bit line 32, the wiring trench 29a that exposes the top via 25a is formed by etching the silicon nitride film 26. At this time, as the result of the variation in the etching within the wafer (the semiconductor substrate) surface, or the like, the surface of the silicon oxide film 20 exposed after the removal of the silicon nitride film 26 may occasionally be etched. In such a case, as shown in FIG. 34, the wiring trench 29a is formed in such a mode that the upper end portion of the top via 25a protrudes from the bottom surface of the wiring trench.

When the cladding layer 30 is formed in such a state that the top via 25a protrudes from the bottom surface of the wiring trench 29a (see FIG. 18), and the whole surface of the cladding layer 30 is etched (see FIG. 19), the portion of the cladding layer covering the side wall of the top via 25a may occasionally be not removed, but left depending on the height H of the protruding top via 25a from the wiring trench 29a.

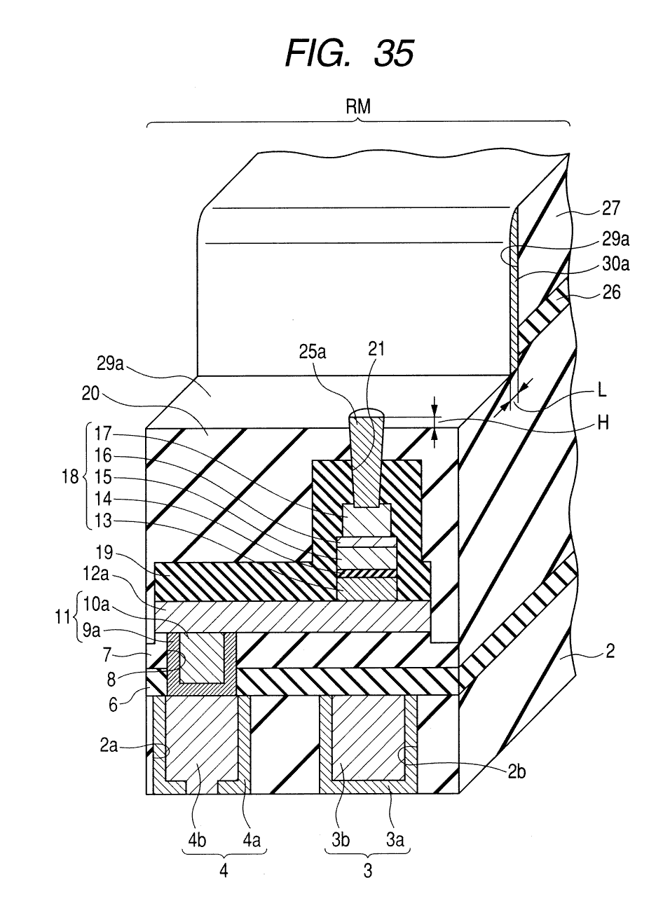

In order not to allow the cladding layer to remain over the side wall of the top via 25a even when the top via 25a protrudes from the bottom surface of the wiring trench 29a, it is therefore desirable, as shown in FIG. 35, to set the etching condition when forming the wiring trench 29a so that the height H of the portion of the protruding top via 25a falls within a range of a height corresponding to the thickness of about two times the thickness L of the cladding layer 30a left over the side wall of the wiring trench 29a (see FIG. 19).

### Example 2

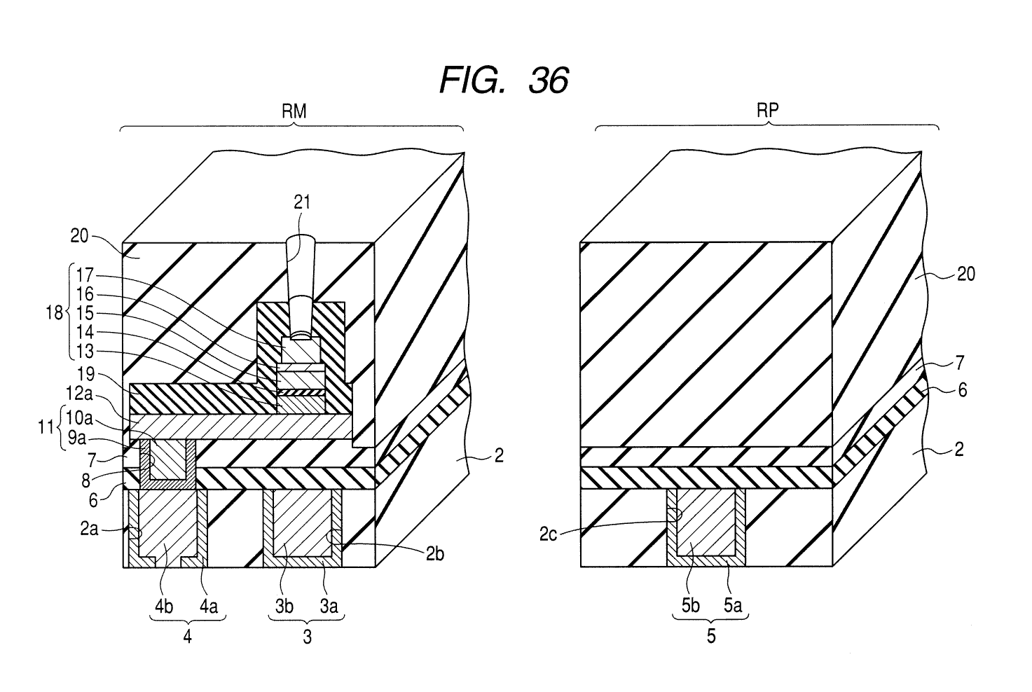

Here, the memory cell formed in the memory cell region and the peripheral circuitry formed in the peripheral circuitry region of the semiconductor device are explained together. Firstly, after the respective formation of prescribed transistor, wiring, via and the like (see the memory cell region RM and the peripheral circuitry region RP in FIG. 3) over the surface of the semiconductor substrate, as shown in FIG. 36, the silicon oxide film 2 is formed. In the silicon oxide film 2 lying in the memory cell region RM, wiring trenches 2a and 2b are formed. In the wiring trench 2a, the wiring 4 for readout constituted by the cladding layer 4a and the copper film 4b is formed, and, in the wiring trench 2b, the digit line 3 constituted by the cladding layer 3a and the copper film 3b is formed. In the silicon oxide film 2 lying in the peripheral circuitry region RP, the wiring trench 2c is formed, and, in the wiring trench 2c, the wiring 5 constituted by the cladding layer 5a and the copper film 5b is formed.

Next, over the silicon oxide film 2, the silicon nitride film 6 is formed so as to cover the digit line 3, the wiring 4 for readout and the wiring 5. Over the silicon nitride film 6, the silicon oxide film 7 is formed. Next, in the memory cell region RM, the magnetoresistive element 18 and the like are formed through the same processes as aforementioned processes shown in FIGS. 5 to 10. So as to cover the magnetoresistive element 18, the silicon oxide film 20 is formed. In the peripheral circuitry region RP, a silicon oxide film 20 is formed, in addition, over the silicon oxide film 7.

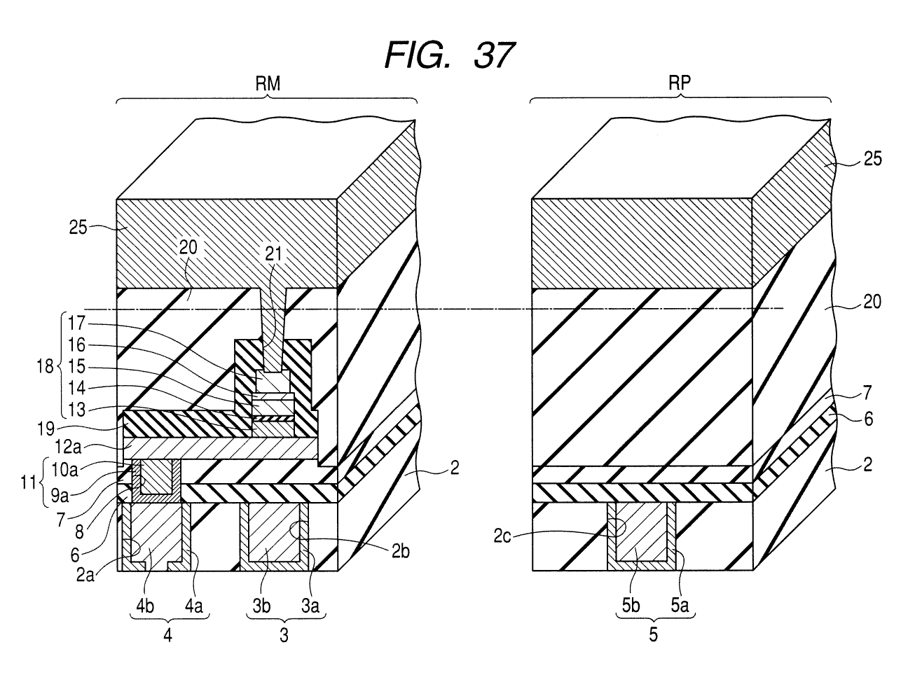

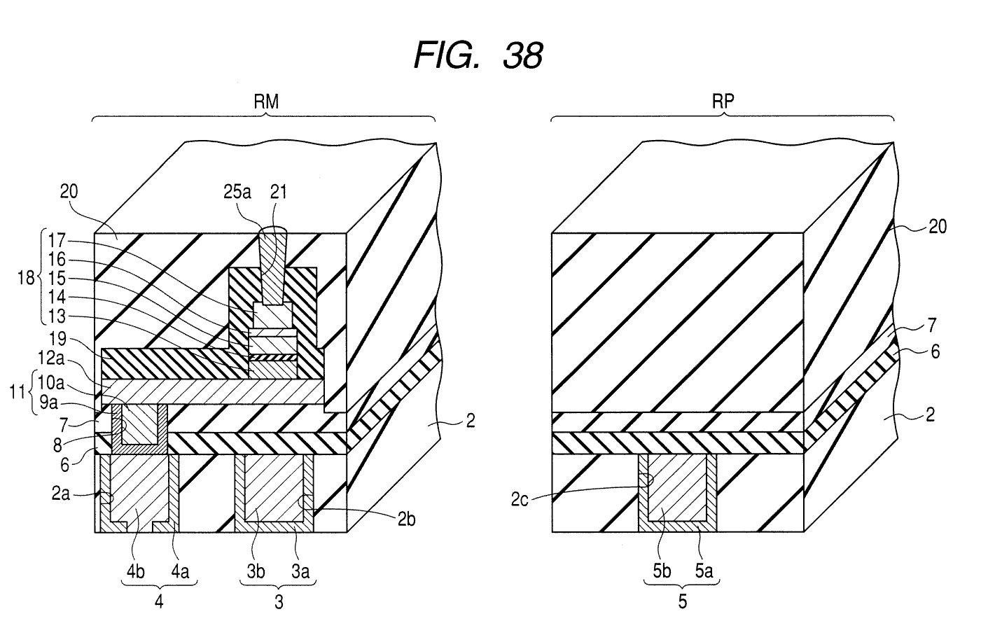

Next, in the memory cell region RM, the top via hole 21 that exposes the surface of the magnetoresistive element 18 is formed. Next, so as to cover the side wall of the top via hole 21, a barrier metal layer (not shown) for preventing the diffusion of copper is formed, and, next, as shown in FIG. 37, the copper film 25 is formed over the silicon oxide film 20 so as to fill up the top via hole 21. Next, by subjecting the copper film 25 to a chemical mechanical polishing treatment, the portion of the copper film 25 lying over the upper surface of the silicon oxide film 20 is removed, and, furthermore, a part of the silicon oxide film 20 is removed (see the position of the dashed one-dotted line). Thus, as shown in FIG. 38, the top via 25a constituted by a non-magnetic material without the cladding layer is formed in the top via hole 21.

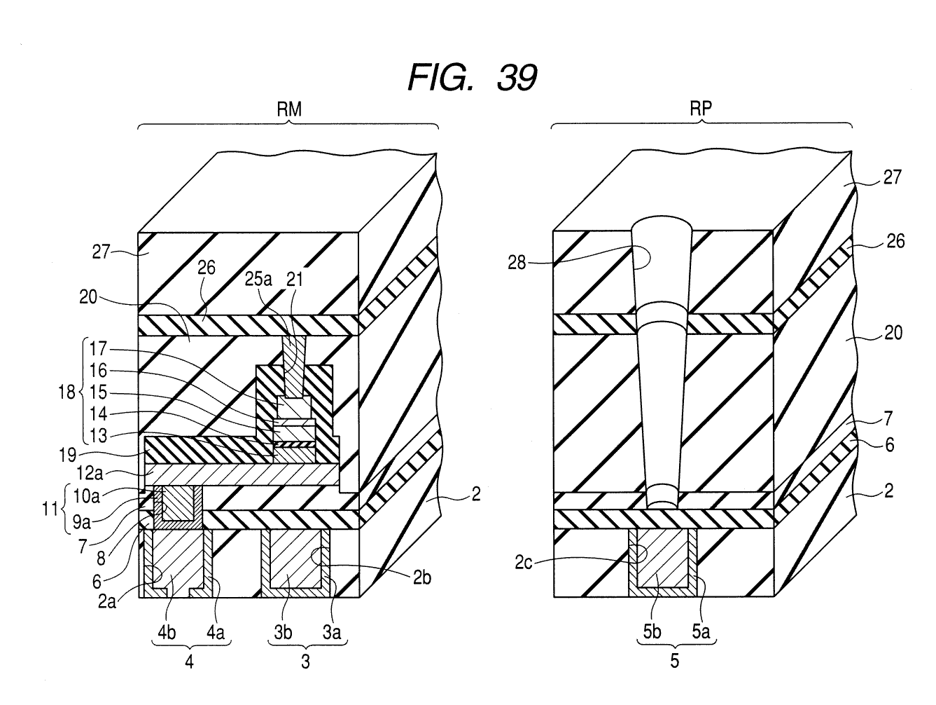

Next, over the silicon oxide film 20, a silicon nitride film 26 (see FIG. 39) is formed, and, furthermore, over the silicon nitride film 26, a silicon oxide film 27 (see FIG. 39) is formed. Next, in the peripheral circuitry region RP, a prescribed resist pattern (not shown) for forming a peripheral circuitry via hole is formed. Next, using the resist pattern as a mask, each of the silicon oxide film 27, the silicon nitride film 26, the silicon oxide film 20 and the silicon oxide film 7 is subjected to a prescribed etching to form the opening 28 that exposes the silicon nitride film 6, as shown in FIG. 39.

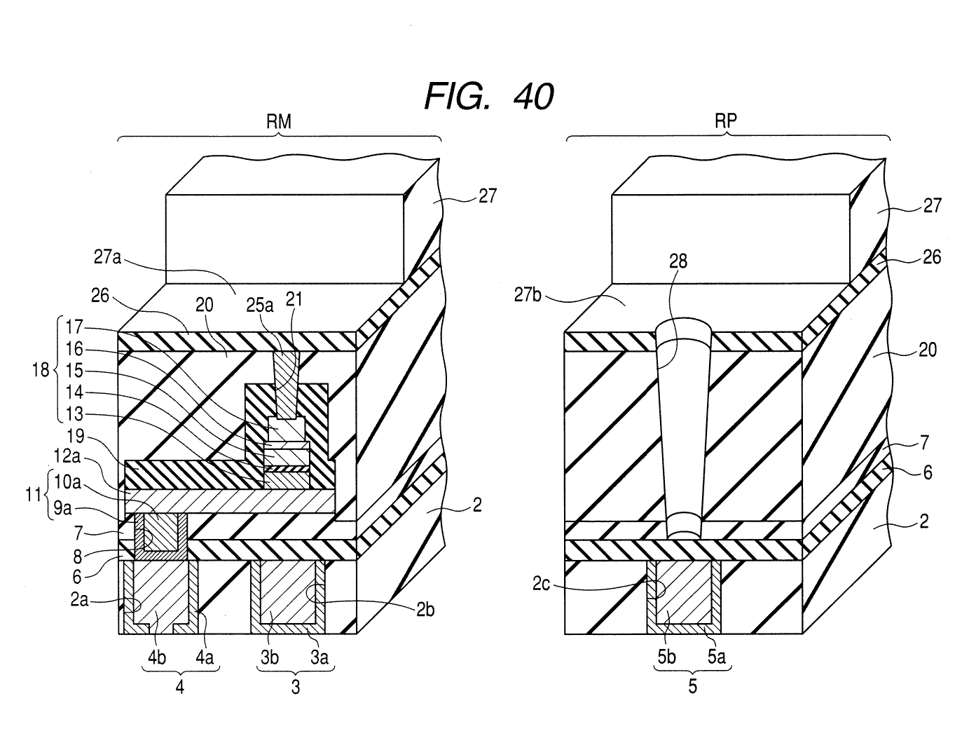

Next, in the memory cell region RM, a resist pattern (not shown) for forming a wiring trench for the bit line is formed over the silicon oxide film 27. In the peripheral circuitry region RP, too, a resist pattern (not shown) for forming a wiring trench for the bit line is formed over the silicon oxide film 27. Next, the silicon oxide film 27 is etched using the resist pattern as a mask to form the opening 27a that exposes the silicon nitride film 26 in the memory cell region RM, and to form the opening 27b that exposes the silicon nitride film 26 in the peripheral circuitry region RP, as shown in FIG. 40.

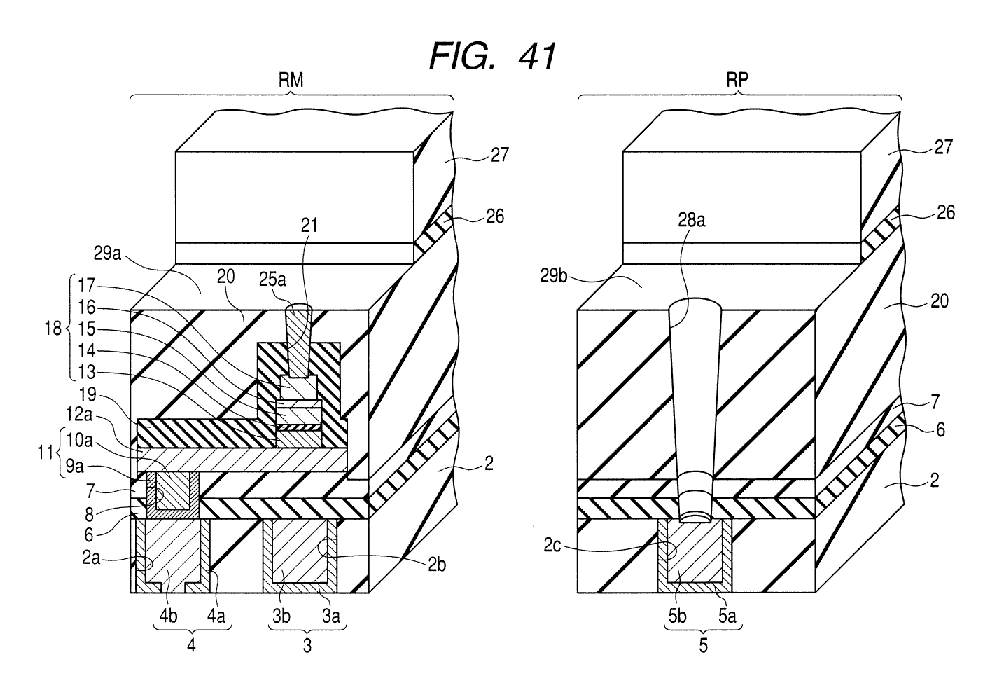

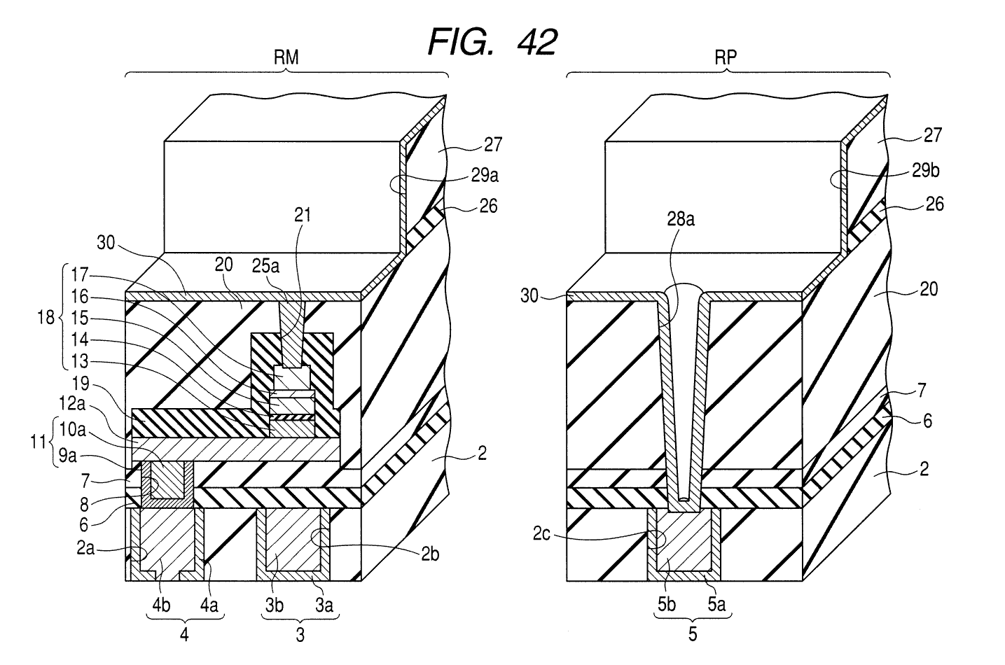

Next, the portion of the silicon nitride film 26 exposed at the bottom surface of the opening 27a in the memory cell region RM, the portion of the silicon nitride film 26 exposed at the bottom surface of the opening 27b in the peripheral circuitry region RP, and the portion of the silicon nitride film 6 exposed at the bottom of the opening 28 are etched to simultaneously remove portions of these silicon nitride films 26 and 6. Thus, as shown in FIG. 41, in the memory cell region RM, the wiring trench 29a that exposes the top via 25a is formed. In the peripheral circuitry region RP, the peripheral circuitry via hole 28a that exposes the wiring 5 and the wiring trench 28b are formed. Next, as shown in FIG. 42, the cladding layer 30 is formed so as to cover the bottom surface and the side wall of the wiring trench 29a in the memory cell region RM, and to cover the bottom surface and the side wall of the wiring trench 29b, the side wall of the peripheral circuitry via hole 28a and the like in the peripheral circuitry region RP.

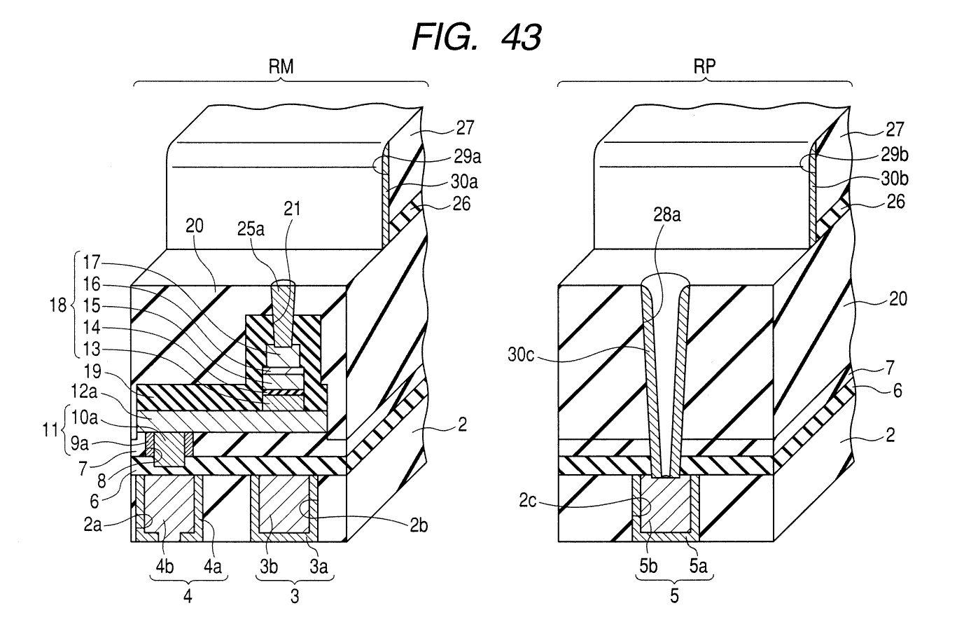

Next, by etching the whole surface of the cladding layer 30, as shown in FIG. 43, in the memory cell region RM, the portion of the cladding layer 30 lying over the bottom surface of the wiring trench 29a, and the portion of the cladding layer 30 lying over the upper surface of the silicon oxide film 27 are removed, while the portion of the cladding layer 30 lying over the side wall of the wiring trench 29a (the cladding layer 30a) is left. In the peripheral circuitry region RP, the portion of the cladding layer 30 lying over the bottom surface of the wiring trench 29b, the portion of the cladding layer 30 lying over the upper surface of the silicon oxide film 27, and the portion of the cladding layer 30 lying at the bottom of the peripheral circuitry via hole 28a are removed, while the portion of the cladding layer 30 lying over side wall of the wiring trench 29b (the cladding layer 30b), and the portion of the cladding layer 30 lying over the side wall of the peripheral circuitry via hole 28a (the cladding layer 30c) are left.

Meanwhile, at this time, the cladding layer 30 may be removed in a mode that leaves a part of the barrier metal film in the cladding layer 30 lying over the respective bottom surfaces of the wiring trenches 29a and 29b, and a part of the barrier metal film in the cladding layer 30 lying over the upper surface of the silicon oxide film 27. Moreover, after that, a barrier metal film (not shown) may be formed so as to cover the respective bottom surfaces of the wiring trenches 29a and 29b, the cladding layer 30a formed over the side wall of the wiring trench 29a, and the cladding layer 30b and the silicon oxide film 27 formed over the side wall of the wiring trench 29b.

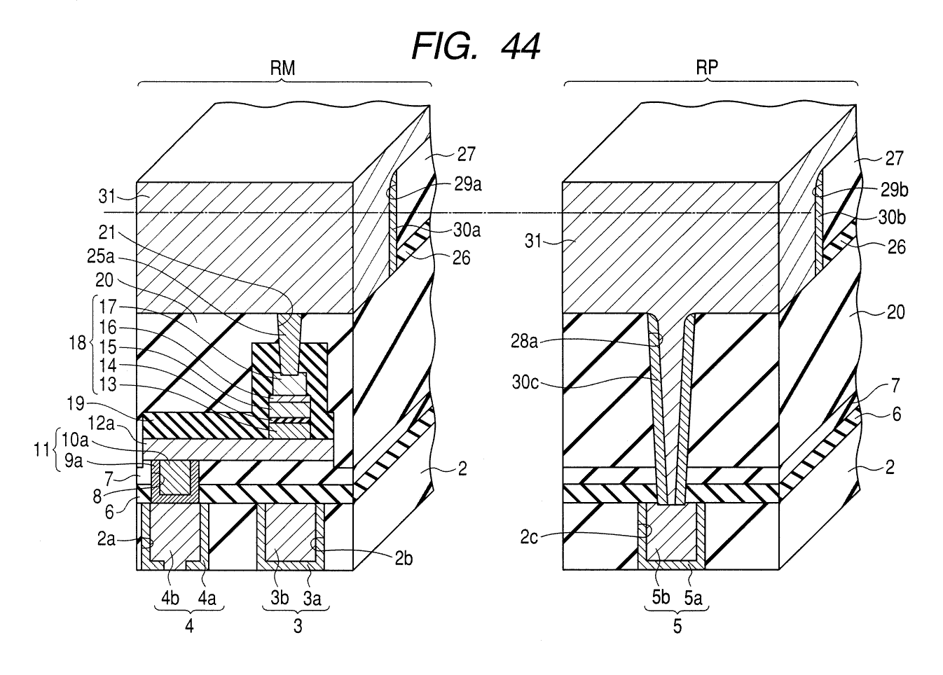

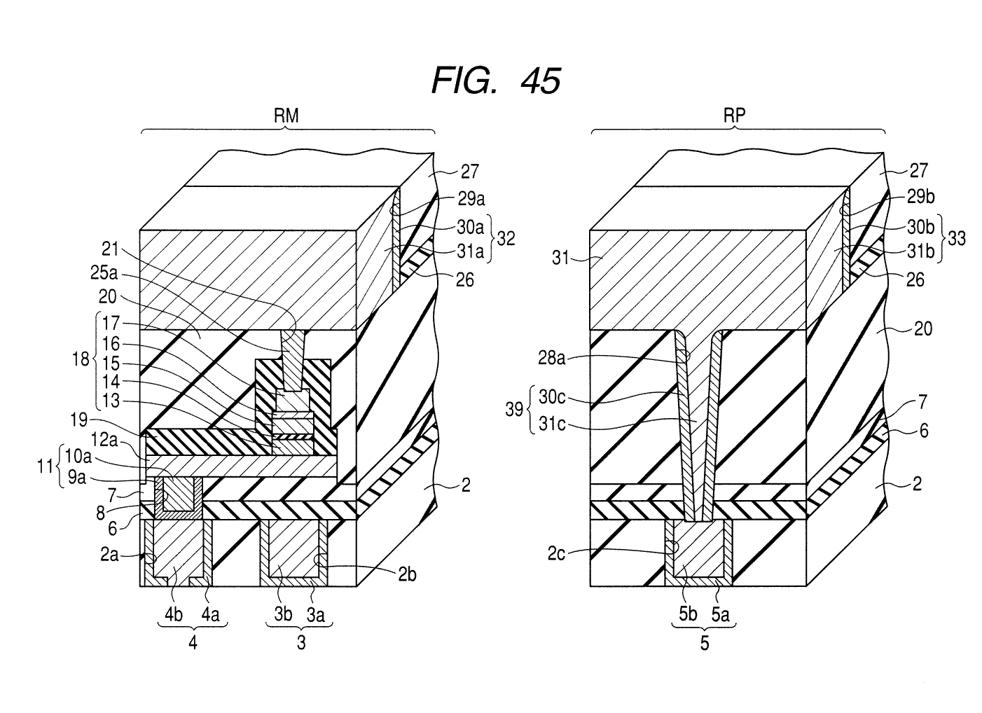

Next, as shown in FIG. 44, a copper film 31 is formed by copper plating so as to fill up the wiring trench 29a in the memory cell region RM, and to fill up the wiring trench 29b and the peripheral circuitry via hole 28a in the peripheral circuitry region RP. Next, by subjecting the copper film 31 to a chemical mechanical polishing treatment, as shown in FIG. 45, in the memory cell region RM, the portion of the copper film 31 lying over the upper surface of the silicon oxide film 27 is removed, while the portion of the copper film 31 lying in the wiring trench 29a (the copper film 31a) is left. In the peripheral circuitry region RP, the portion of the copper film 31 lying over the upper surface of the silicon oxide film 27 is removed while the portion of the copper film 31 lying in the wiring trench 29b (the copper film 31b) and the portion of the copper film lying in the peripheral circuitry via hole 28a are left.

Thus, in the memory cell region RM, the bit line 32 constituted by the cladding layer 30a and the copper film 31a is formed in the wiring trench 29a. In the peripheral circuitry region RP, a bit line 33 constituted by the cladding layer 30b and the copper film 31b is formed in the wiring trench 29b. Further, in the peripheral circuitry via hole 28a, a peripheral circuitry via 39 constituted by a copper film 31c and a cladding layer 30c is formed. The bit line 33 is electrically coupled to the lower wiring 5 via the peripheral circuitry via 39.

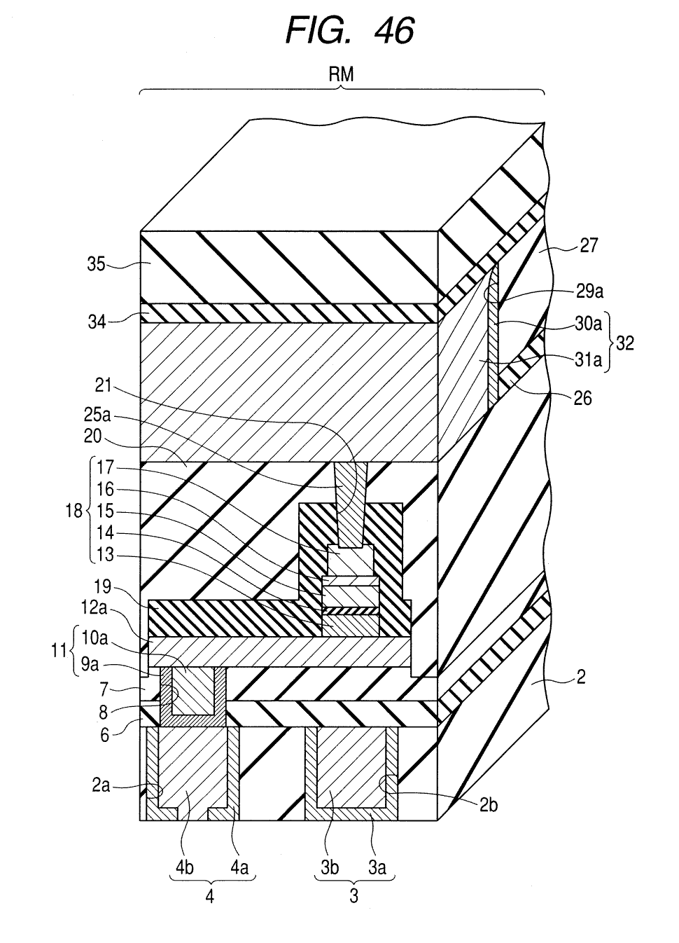

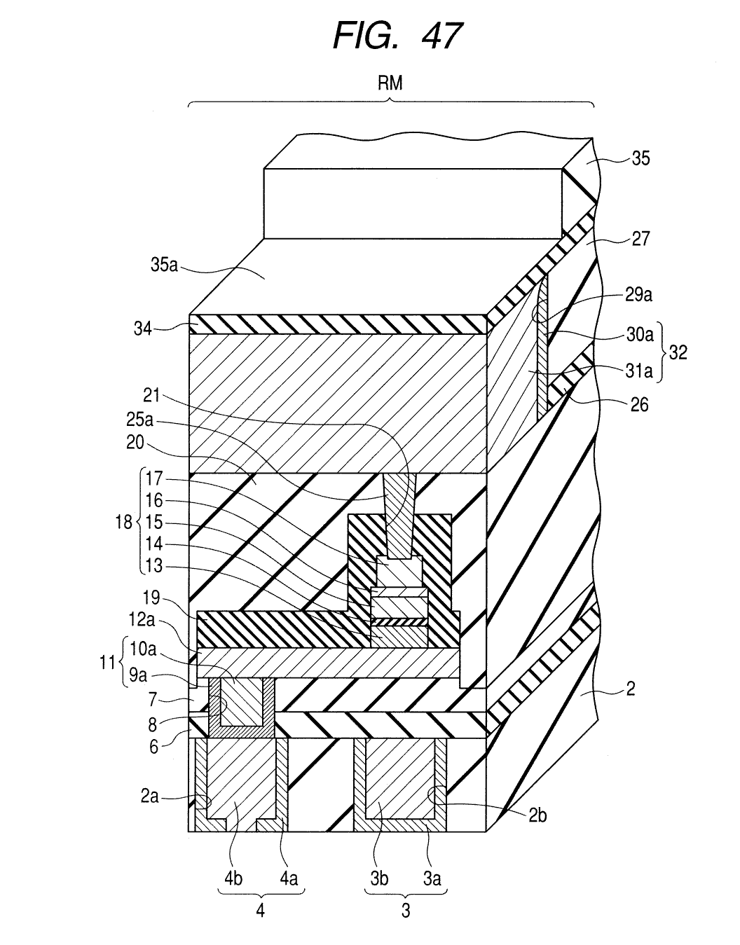

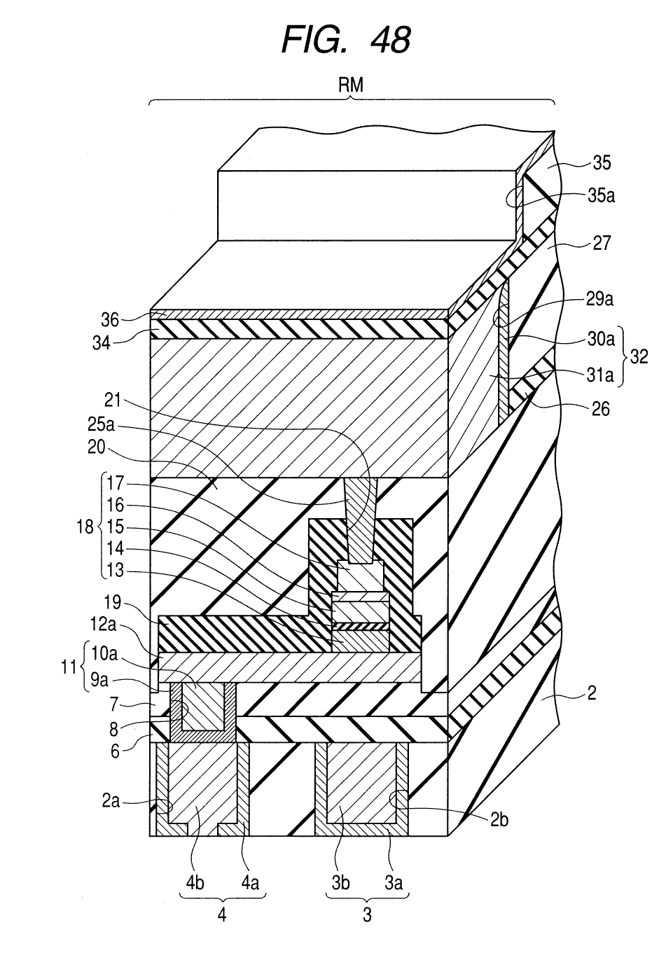

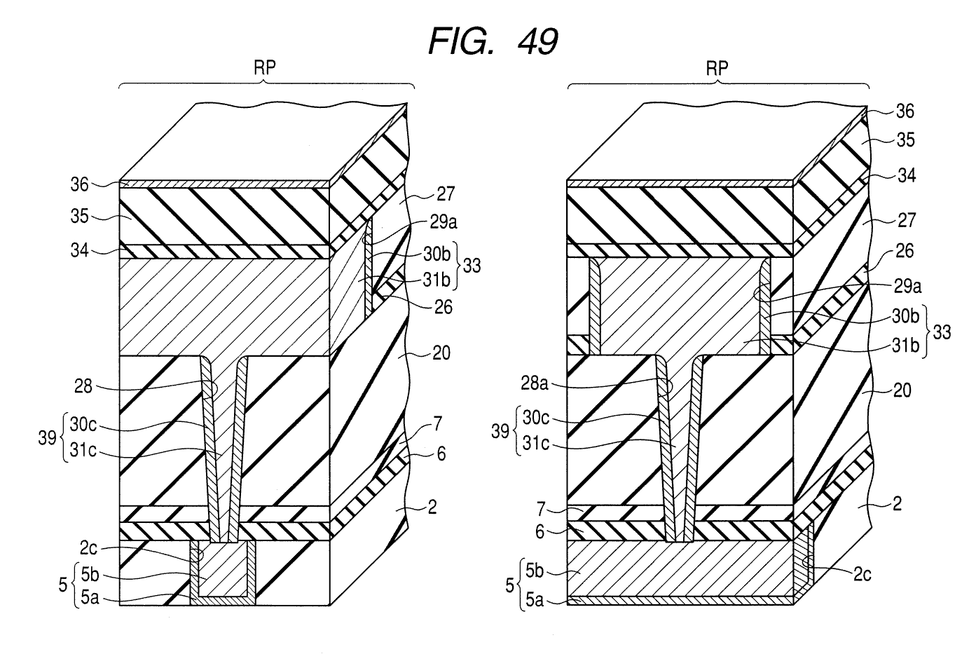

Next, in the memory cell region RM, the cladding layer covering the bit line is formed by the same processes as aforementioned processes shown in FIGS. 22 to 26. As shown in FIG. 46, a silicon nitride film 34 and a silicon oxide film 35 are formed so as to cover the bit line 32. Next, as shown in FIG. 47, an opening 35a is formed in the silicon oxide film 35. Next, as shown in FIG. 48, so as to cover the bottom surface and the side wall of the opening 35a, a cladding layer 36 is formed. At this moment, as shown in FIG. 49, the peripheral circuitry region RP is in such a state that the silicon nitride film 34, the silicon oxide film 35 and the cladding layer 36 are formed so as to cover the bit line 33.

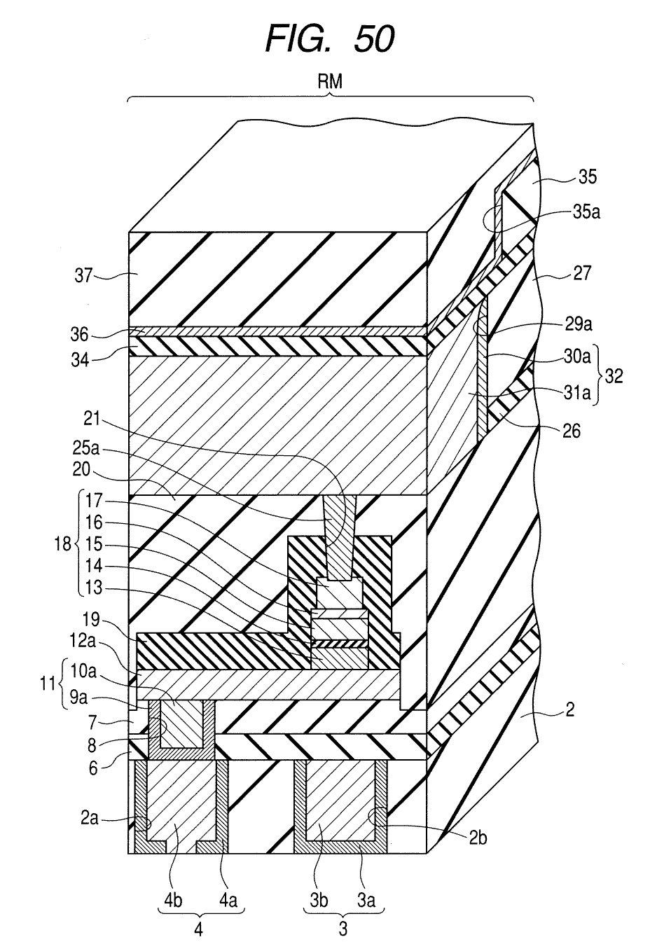

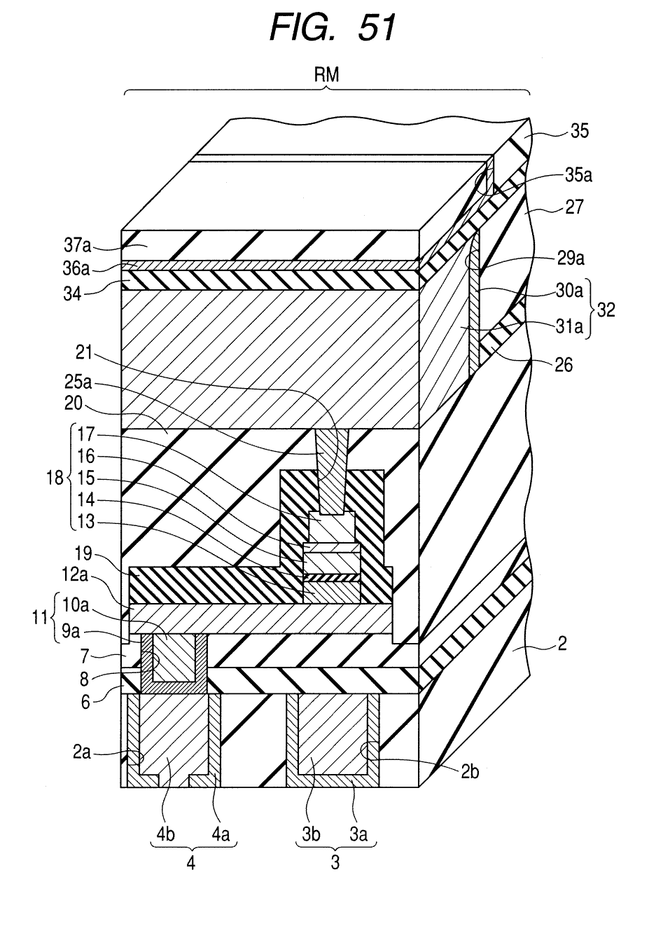

Next, as shown in FIG. 50, in the memory cell region RM, a silicon oxide film 37 is formed so as to fill up the opening 35a. Next, as shown in FIG. 51, by a chemical mechanical polishing treatment, the portion of the cladding layer 36 lying in regions other than the opening 35a is removed while the portion of the cladding layer 36 lying over the side wall and the bottom surface of the opening 35a (the cladding layer 36a) is left, to form the cladding layer 36a covering the bit line 32 from above.

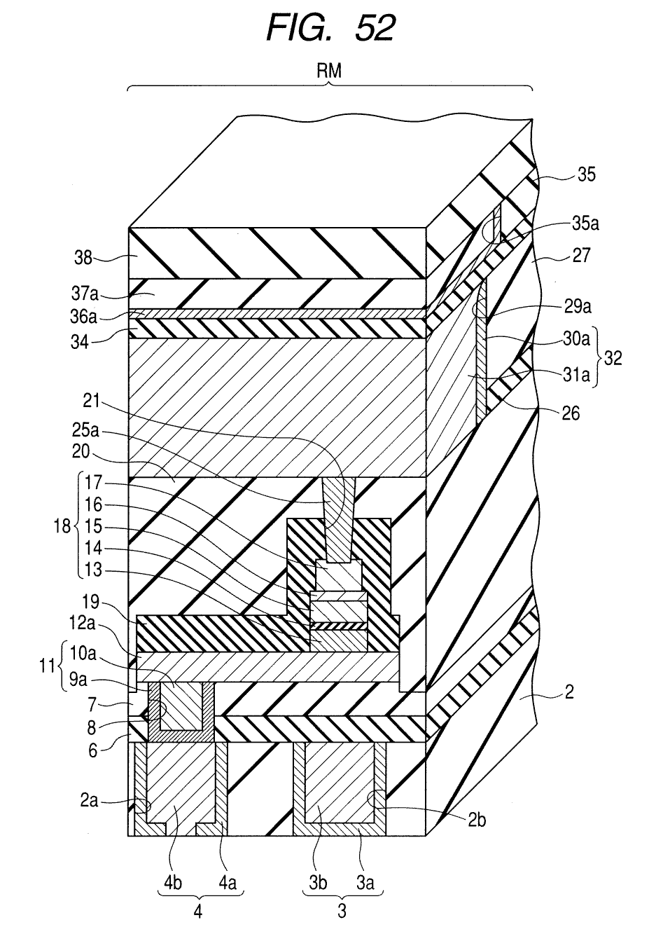

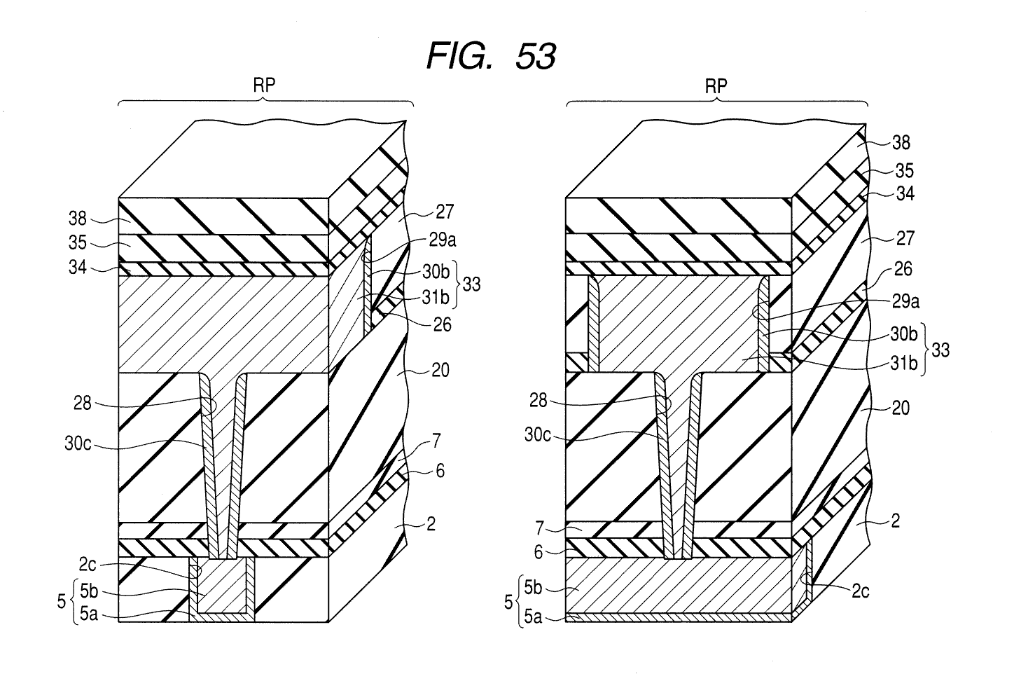

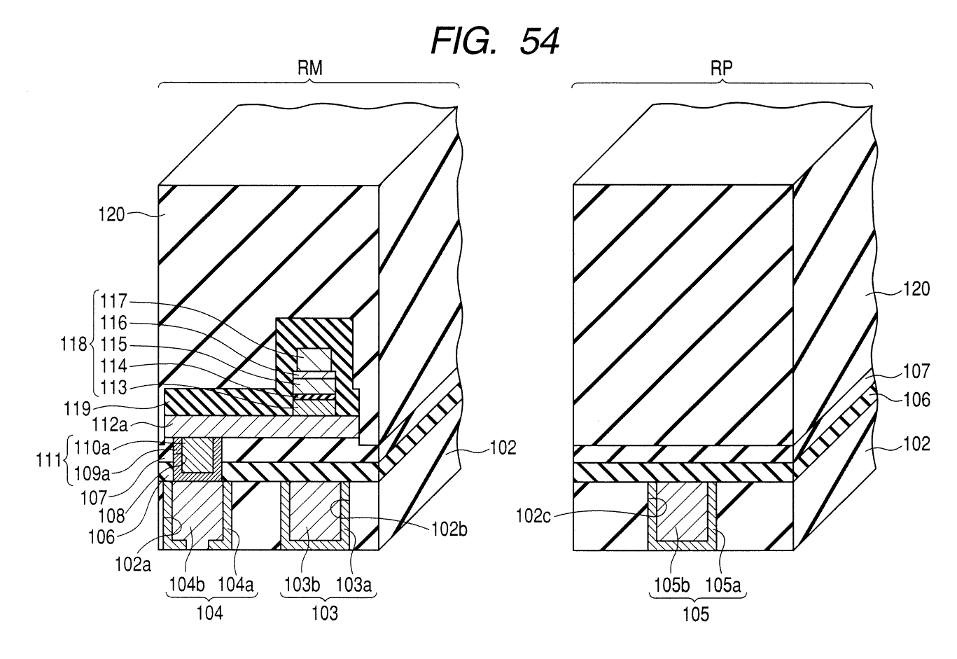

Next, as shown in FIG. 52, the silicon oxide film 38 is formed so as to cover the silicon oxide film 35 and the like, to form the main portion of the memory cell. At this moment, as shown in FIG. 53, the peripheral circuitry region RP is in such a state that the silicon oxide film 38 is formed over the silicon oxide film 35.

In the above-described semiconductor device, in addition to the aforementioned effect obtained due to the fact that the top via does not include the cladding layer, the optimization of the condition for forming the peripheral circuitry via hole may easily be achieved without causing damage to the magnetoresistive element, because the process of forming the peripheral circuitry via hole in the peripheral circuitry region RP is a process separated from the process of forming the top via hole in the memory cell region. This is explained in relation to Comparative Example.

Firstly, since processes of forming the memory cell in the semiconductor device according to Comparative Example are the same as those shown in FIGS. 28 to 33, the same symbol is given to the same member. As shown in FIG. 54, in a silicon oxide film 102 lying in the memory cell region RM, wiring trenches 102a and 102b are formed. In the wiring trench 102a, the wiring 104 for readout constituted by the cladding layer 104a and the copper film 104b is formed, and, in the wiring trench 102b, the digit line 103 constituted by the cladding layer 103a and the copper film 103b is formed. In a silicon oxide film 102 lying in the peripheral circuitry region RP, the wiring trench 102c is formed, and, in the wiring trench 102c, a wiring 105 constituted by a cladding layer 105a and a copper film 105b is formed.

Next, so as to cover the digit line 103, the wiring 104 for readout and the wiring 105, the silicon nitride film 106 is formed over the silicon oxide film 102. Over the silicon nitride film 106, the silicon oxide film 107 is formed. Next, in the memory cell region RM, the magnetoresistive element 118 and the like are formed. So as to cover the magnetoresistive element 118, the silicon oxide film 120 is formed. In the peripheral circuitry region RP, furthermore, the silicon oxide film 120 is formed over the silicon oxide film 107.

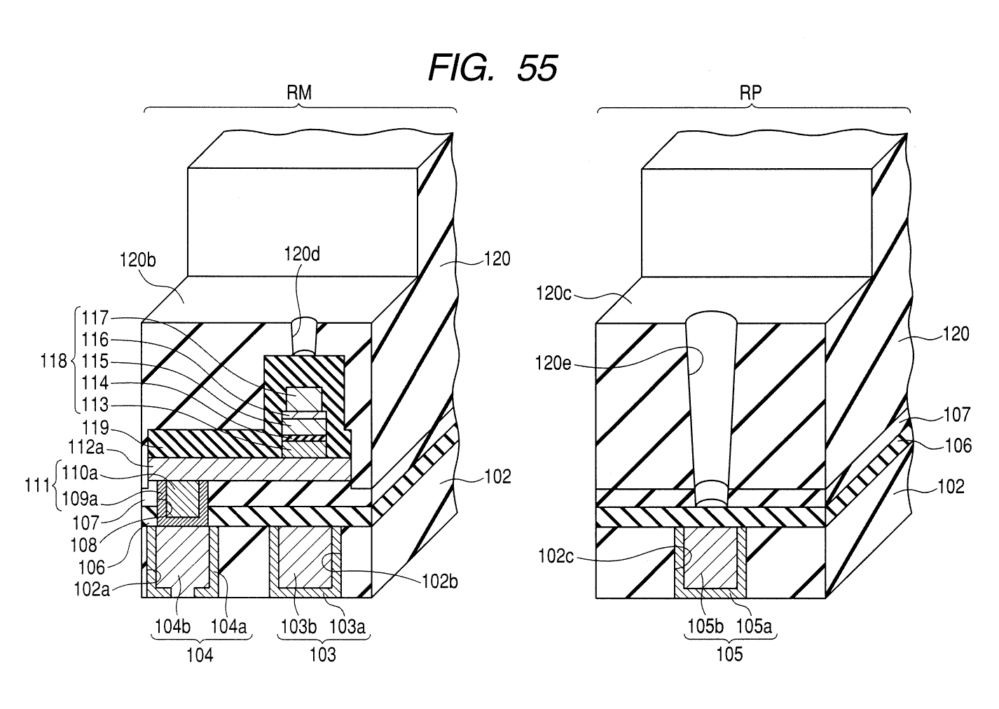

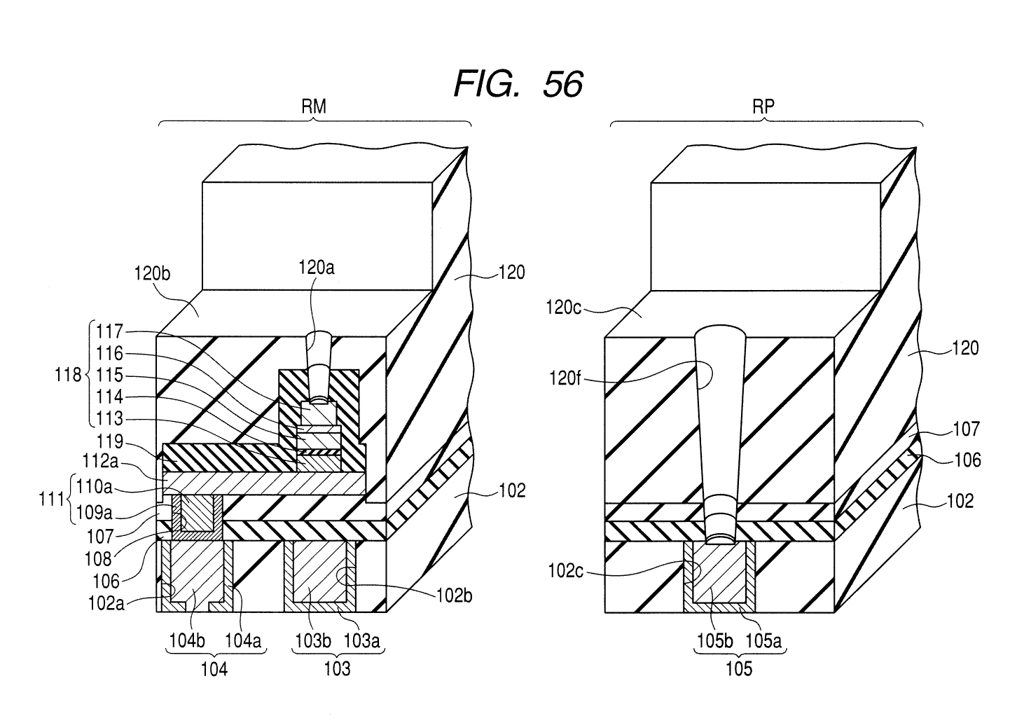

Next, as shown in FIG. 55, in the memory cell region RM, an opening 120d to be the top via hole and a wiring trench 120b for the bit line are formed, and, in the peripheral circuitry region RP, a wiring trench 120c for the bit line and an opening 120e to be the peripheral circuitry via hole are formed, by dual damascene. The opening 120d is formed so as to expose the silicon nitride film 119 covering the magnetoresistive element 118, and the opening 120e is formed so as to expose the silicon nitride film 106 covering the wiring 105.

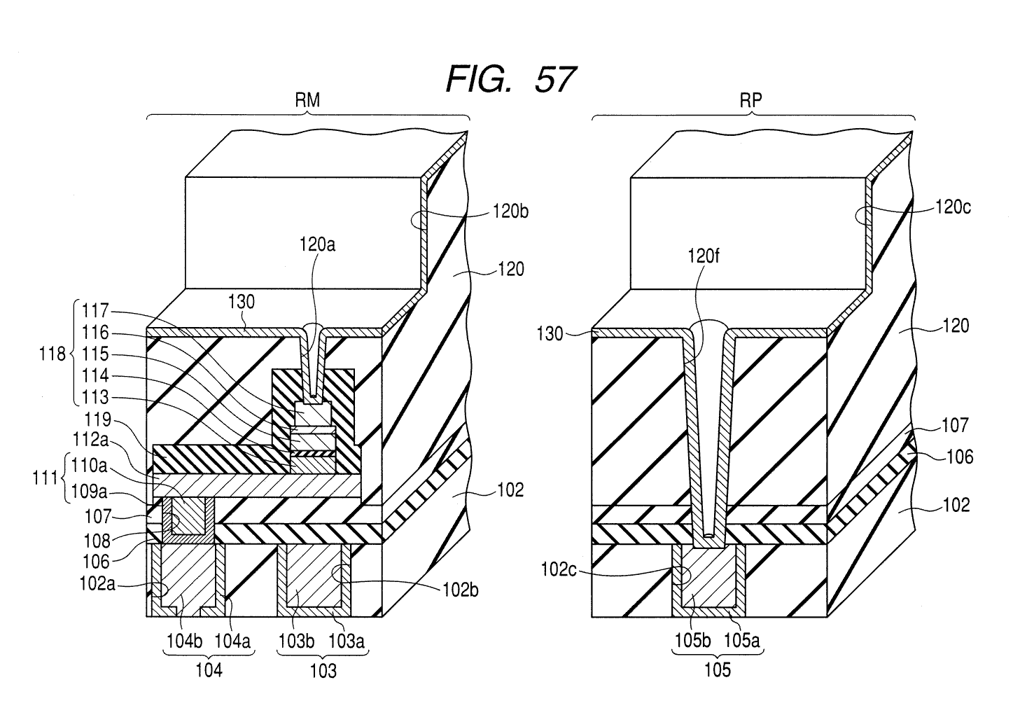

Next, as shown in FIG. 56, the portion of the silicon nitride film 119 exposed at the bottom of the opening 120d, and the portion of the silicon nitride film 106 exposed at the bottom of the opening 120e are removed simultaneously by etching, and, in the memory cell region RM, a top via 120a that exposes the magnetoresistive element 118 is formed. In the peripheral circuitry region RP, a peripheral circuitry via hole 120f that exposes the wiring 105 is formed. Next, as shown in FIG. 57, the cladding layer 130 is formed over the silicon oxide film 120 so as to cover the bottom surface and the side wall of the wiring trenches 120b and 120c. At this time, the cladding layer 130 is also formed over the side wall of the top via hole 120a opening at the bottom surface of the wiring trench 120b, the side wall of the peripheral circuitry via hole 120f opening at the bottom surface of the wiring trench 120c, and the like.

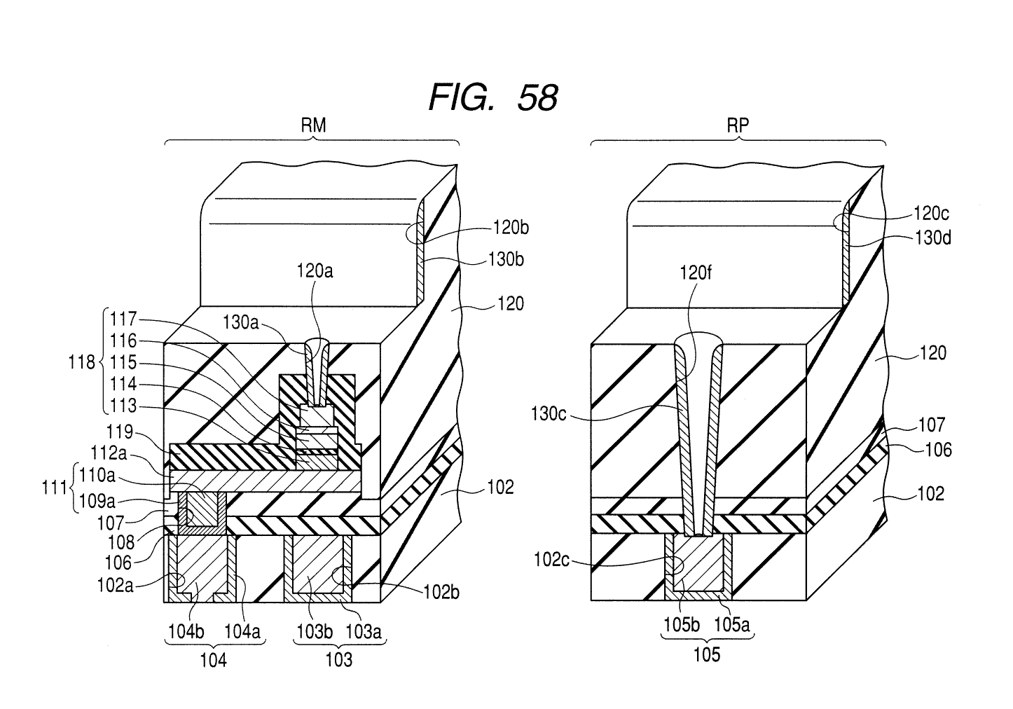

Next, by etching the whole surface of the cladding layer 130, as shown in FIG. 58, in the memory cell region RM, the portion of the cladding layer lying over the bottom surface of the wiring trench 120b and the portion of the cladding layer lying over the upper surface of the silicon oxide film 120 are removed, while the portion of the cladding layer lying over the side wall of the wiring trench 120b (the cladding layer 130b) is left. In the peripheral circuitry region RP, the portion of the cladding layer lying over the bottom surface of the wiring trench 120c, and the portion of the cladding layer lying over the upper surface of the silicon oxide film 120 are removed, while the portion of the cladding layer lying over the side wall of the wiring trench 120c (the cladding layer 130d) is left.

At this time, the portion of the cladding layer formed over the side wall of the top via hole 120a (the cladding layer 130a) is not removed but left. Further, the portion of the cladding layer formed over the side wall of the peripheral circuitry via hole 120f (the cladding layer 130c), too, is not removed but left.

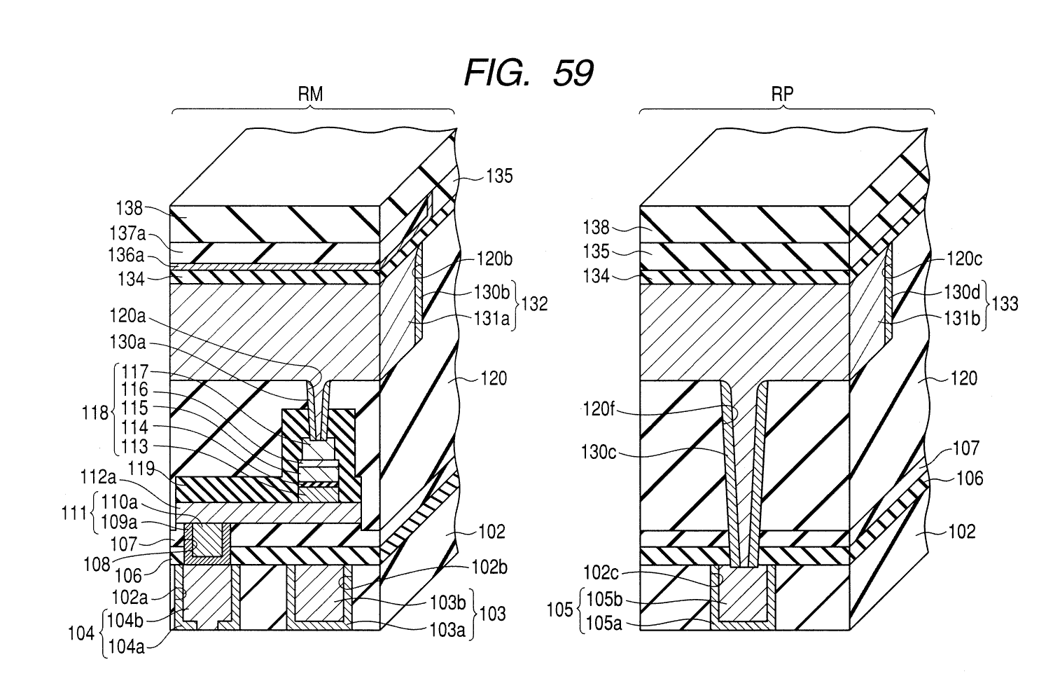

Next, as shown in FIG. 59, in the memory cell region RM, the bit line 132 constituted by the cladding layer 130b and the copper film 131a is formed in the wiring trench 120b. Next, over the bit line 132, the cladding layer 136a covering the bit line 132 is formed via the silicon nitride film 134. After that, the silicon oxide film 137a is formed so as to cover the cladding layer 136a, and, furthermore, the silicon oxide film 138 is formed.

In the peripheral circuitry region RP, a bit line 133 constituted by the cladding layer 130d and the copper film 131b is formed in the wiring trench 120c. Over the bit line 133, a silicon oxide film 135 is formed via the silicon nitride film 134, and, furthermore, a silicon oxide film 138 is formed. In the semiconductor device according to Comparative Example, the main portion thereof is formed as described above.

In the semiconductor device according to Comparative Example, as described above, in the memory cell region RM, the portion of the silicon nitride film 119 exposed at the bottom of the opening 120d, and, in the peripheral circuitry region RP, the portion of the silicon nitride film 106 exposed at the bottom of the opening 120e are simultaneously removed by etching (see FIG. 56).

The silicon nitride film 106 is formed prior to the formation of the magnetoresistive element 118, and is formed under the condition of a comparatively high temperature. On the other hand, the silicon nitride film 119 is formed after the formation of the magnetoresistive element 118, and, therefore, is formed under the condition of a relatively low temperature (about 300° C. or less). Consequently, concerning the denseness of the film, the silicon nitride film 106 becomes denser than the silicon nitride film 119, and, under the same etching condition, the etching rate of the silicon nitride film 119 is greater than that of the silicon nitride film 106.

In this case, when trying to surely remove the portion of the silicon nitride film 106 exposed at the bottom of the opening 120e in the peripheral circuitry region RP, the etching is continued even after the removal of the portion of the silicon nitride film 119 exposed at the bottom of the opening 120d in the memory cell region RM, and damage may occasionally be given to a magnetic memory element 118. In contrast, when trying to remove the portion of the silicon nitride film 119 exposed at the bottom of the opening 120d with the intention of not causing damage to the magnetic memory element 118, the portion of the silicon nitride film 106 exposed at the bottom of the opening 120e in the peripheral circuitry region RP can not surely be removed. In the semiconductor device according to Comparative Example, it becomes therefore hard to achieve the optimization of the etching condition of simultaneously removing the silicon nitride film 119 in the memory cell region RM and the silicon nitride film 106 in the peripheral circuitry region RP.

In contrast, in the aforementioned semiconductor device, the top via hole 21 in the memory cell region RM is formed, the top via 25a is formed in the top via hole 21, and then the peripheral circuitry via hole 28a in the peripheral circuitry region RP is formed. Consequently, it is possible to set the etching condition for forming the peripheral circuitry via hole in the peripheral circuitry region RP without any regard for the etching condition for forming the top via hole, and to easily achieve the optimization of the etching condition.

In addition, it is possible to set the etching condition of the top via hole 21 in the memory cell region RM without any regard for the etching condition for forming the peripheral circuitry via hole in the peripheral circuitry region RP, and to easily achieve the optimization of the etching condition.

Thus, the aforementioned semiconductor device gives such an effect that the rewrite property does not deteriorate because the top via 25a does not include the cladding layer, and, in addition, enables the etching condition for forming the top via hole 21 in the memory cell region RM and the etching condition for forming the peripheral circuitry via hole in the peripheral circuitry region RP to be optimized individually. Consequently, in the memory cell region RM, it is possible to electrically couple the bit line 32 and the magnetoresistive element 18 without causing damage to the magnetoresistive element 18, and to surely electrically couple the bit line 33 and the wiring 5 in the peripheral circuitry region RP.

Meanwhile, in the aforementioned semiconductor device, since the silicon nitride film 26 is formed after the formation of the magnetoresistive element 18 as is the case for the silicon nitride film 19, under the same etching condition, the etching rate of the silicon nitride film 26 is greater than that of the silicon nitride film 6 that is formed prior to the formation of the magnetoresistive element 18.

Hence, when simultaneously removing, by etching, the portion of the silicon nitride film 26 exposed at the bottom surface of the opening 27a in the memory cell region RM, the portion of the silicon nitride film 26 exposed at the bottom surface of the opening 27b in the peripheral circuitry region RP, and the portion of the silicon nitride film 6 exposed at the bottom of the opening 28 (see FIG. 40), it is assumed that the etching is continued even after the removal of the silicon nitride film 26 to etch the surface of the exposed silicon oxide film 20 (see FIG. 41), and that the upper end portion of the top via 25a protrudes from the surface of the silicon oxide film 20.

As explained already, when the top via 25a protrudes from the bottom surface of the wiring trench 29a, the cladding layer is occasionally not removed but left over the side wall of the top via 25a. Hence, in order not to allow the cladding layer to remain over the side wall of the top via 25a, it is desirable to set the etching condition of the silicon nitride films 26 and 6 so that the height H of the portion of the protruding top via 25a falls within a range of a height corresponding to the thickness of about two times the thickness L of the cladding layer 30a left over the side wall of the wiring trench 29a (see FIG. 35).

In addition, in the aforementioned semiconductor device, when etching the whole surface of the cladding layer 30, the portion of the cladding layer 30 lying over the side wall of the peripheral circuitry via hole 28a in the peripheral circuitry region RP (the cladding layer 30c) is not completely removed but left (see FIG. 43). According to the evaluation of the present inventors, it was confirmed that the remaining cladding layer 30c in the peripheral circuitry via hole 28a in the peripheral circuitry region RP further increases the reliability of the wiring.

It is considered that the remaining cladding layer 30c in the peripheral circuitry via hole 28a prevents the magnetic field generated by the current flowing through the copper film in the peripheral circuitry via hole 28a from leaking to the outside of the peripheral circuitry via hole 28a to suppress the influence of the magnetic field on the magnetoresistive element 18.

### Example 3

Here, particularly, a semiconductor device, in which no cladding layer is formed in the peripheral circuitry via hole in the peripheral circuitry region and a peripheral circuitry via including no cladding layer is provided as the peripheral circuitry via, is explained.

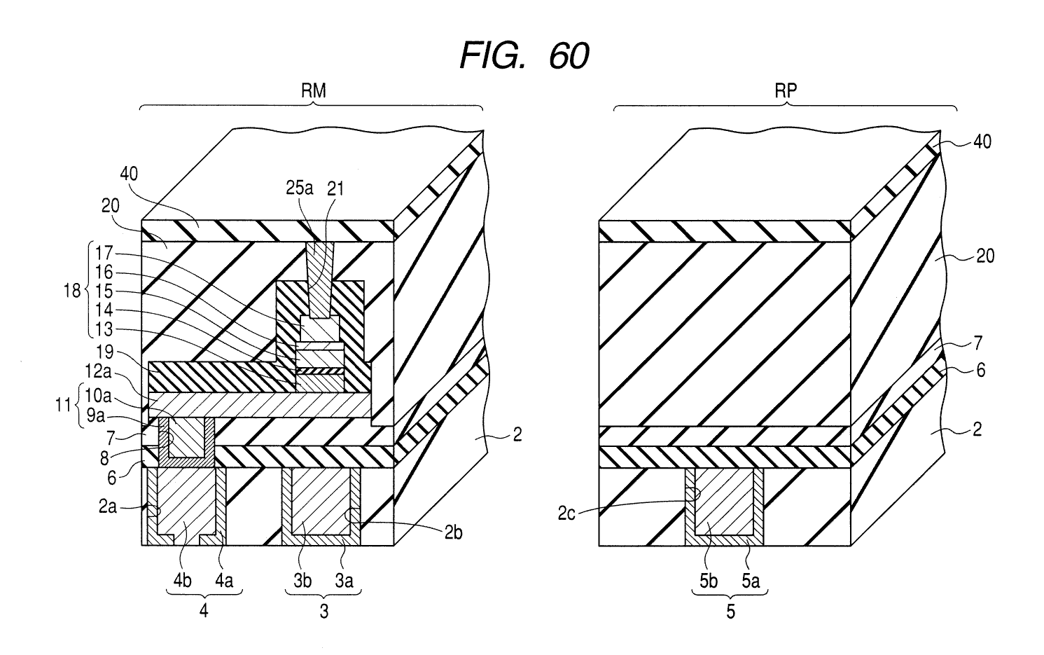

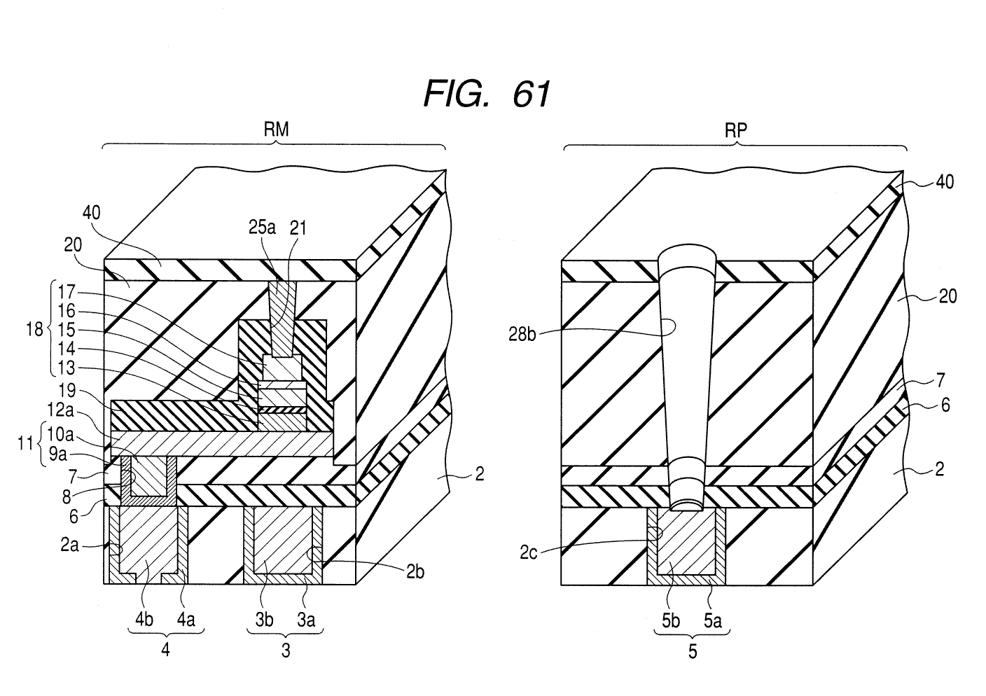

After going through the same processes as aforementioned processes shown in FIGS. 36 to 38, a silicon nitride film 40 is formed over the silicon oxide film 20 as shown in FIG. 60. Next, over the silicon nitride film 40, a resist pattern (not shown) for forming the peripheral circuitry via hole in the peripheral circuitry region is formed. Using the resist pattern as a mask, the silicon nitride film 40 and the like are etched to form the peripheral circuitry via hole 28b that exposes the wiring 5, as shown in FIG. 61. Next, so as to cover the side wall of the peripheral circuitry via hole 28b, a barrier metal layer (not shown) for preventing the diffusion of copper is formed. The barrier metal layer does not include the cladding layer.

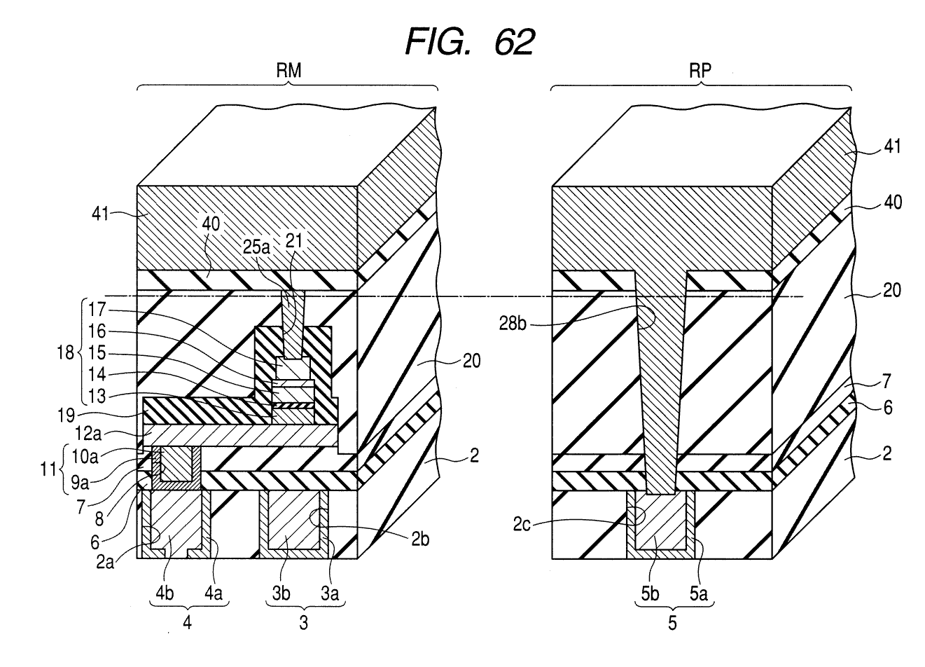

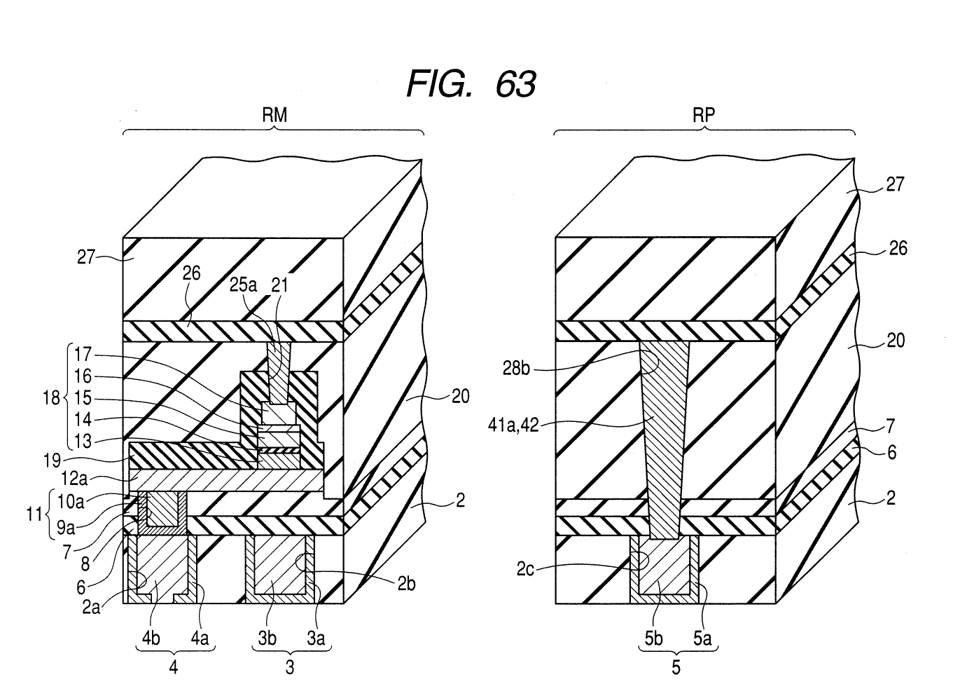

Next, as shown in FIG. 62, over the silicon nitride film 40, a copper film 41 is formed by copper plating so as to fill up the peripheral circuitry via hole 28b. Next, the copper film 41 is subjected to a chemical mechanical polishing treatment to remove the portion of the copper film 41 lying over the upper surface of the silicon nitride film 40 and, furthermore, a part of the silicon nitride film 40 and silicon oxide film 20 (see the position of dashed one-dotted line). Thus, as shown in FIG. 63, in the peripheral circuitry via hole 28b, a peripheral circuitry via 42 constituted by a copper film 41a including no cladding layer is formed. Next, over the silicon oxide film 20, the silicon nitride film 26 is formed, and, furthermore, over the silicon nitride film 26, the silicon oxide film 27 is formed.

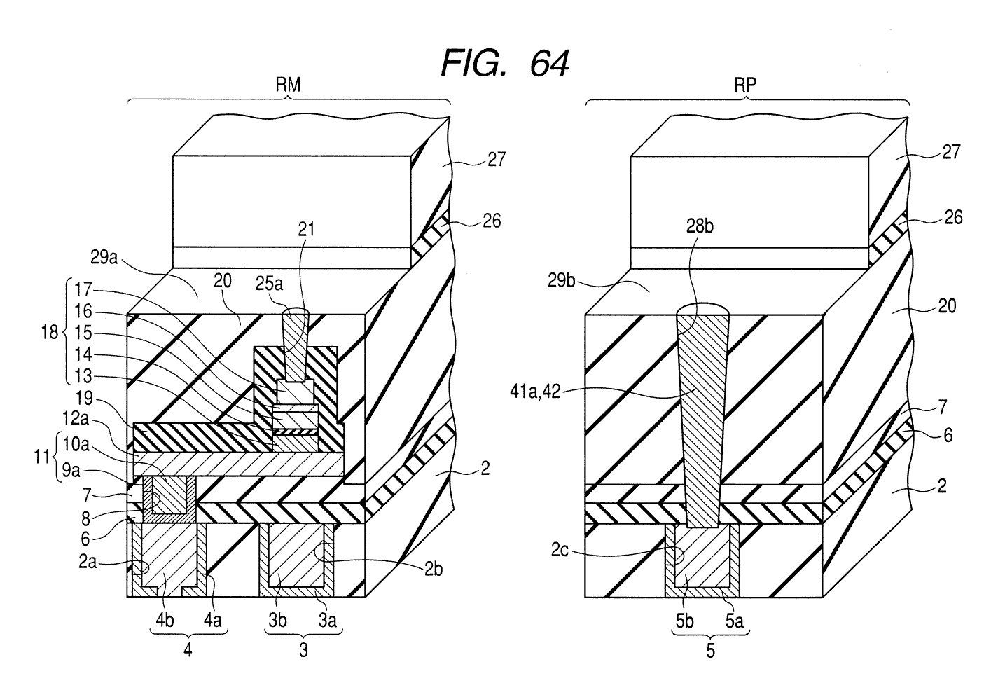

Next, a resist pattern (not shown) for forming a wiring trench for the bit line is formed over the portion of the silicon oxide film 27 in the memory cell region RM and the portion of the silicon oxide film 27 in the peripheral circuitry region RP. Next, the silicon oxide film 27 is etched using the resist pattern as a mask to expose the silicon nitride film 26, and, furthermore, the exposed silicon nitride film 26 is etched, as shown in FIG. 64, to form the wiring trench 29a that exposes the top via 25a in the memory cell region RM. In the peripheral circuitry region RP, the wiring trench 29b that exposes the peripheral circuitry via 42 is formed.

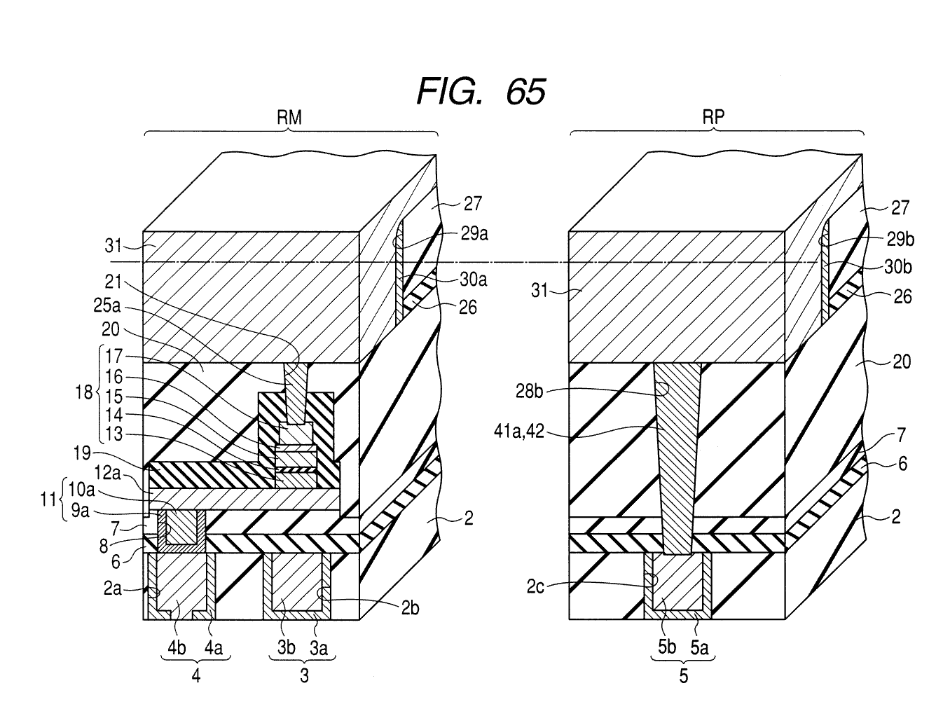

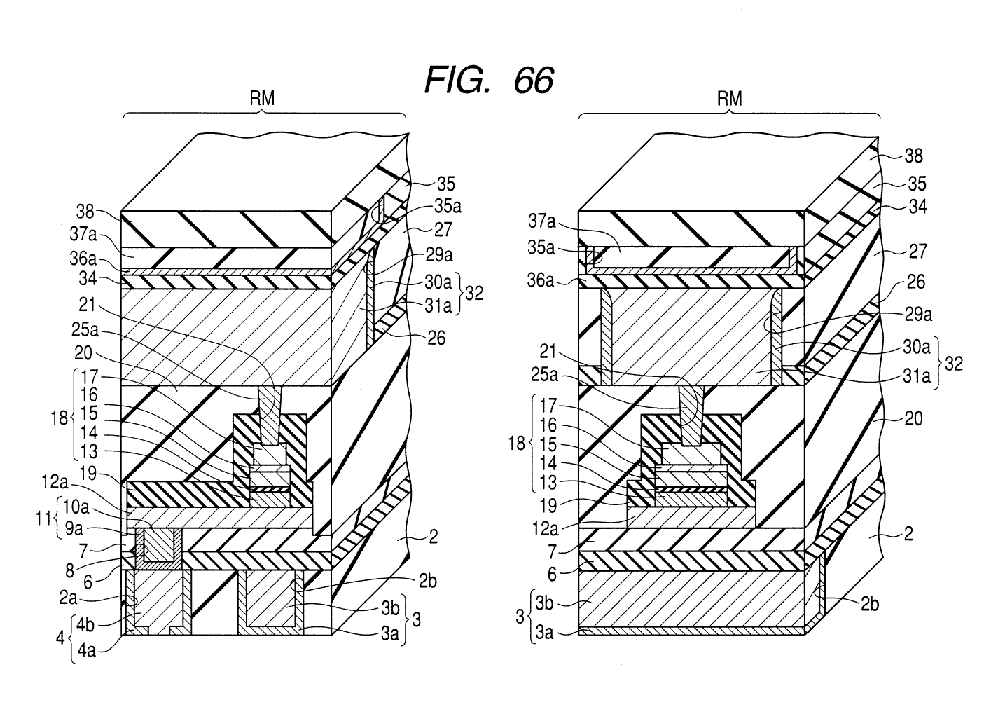

Next, so as to cover the bottom surface and the side wall of the wiring trenches 29a and 29b, the cladding layer (not shown) is formed. Next, the whole surface of the cladding layer is etched, and, as shown in FIG. 65, in the memory cell region RM, the cladding layer 30a is formed over the side wall of the wiring trench 29a, and, in the peripheral circuitry region RP, the cladding layer 30b is formed over the side wall of the wiring trench 29b. Next, in the memory cell region RM, the copper film 31 is formed by copper plating so as to fill up the wiring trenches 29a and 29b.

Meanwhile, at this time, the cladding layer 30 may be removed in a mode that leaves a part of the barrier metal film in the cladding layer 30 lying over each bottom surface of the wiring trenches 29a and 29b. Further, after that, a barrier metal film (not shown) may be formed so as to cover the cladding layer 30a formed over each bottom surface of the wiring trenches 29a and 29b and over the side wall of the wiring trench 29a, and the cladding layer 30b and the silicon oxide film 27 formed over the side wall of the wiring trench 29b.

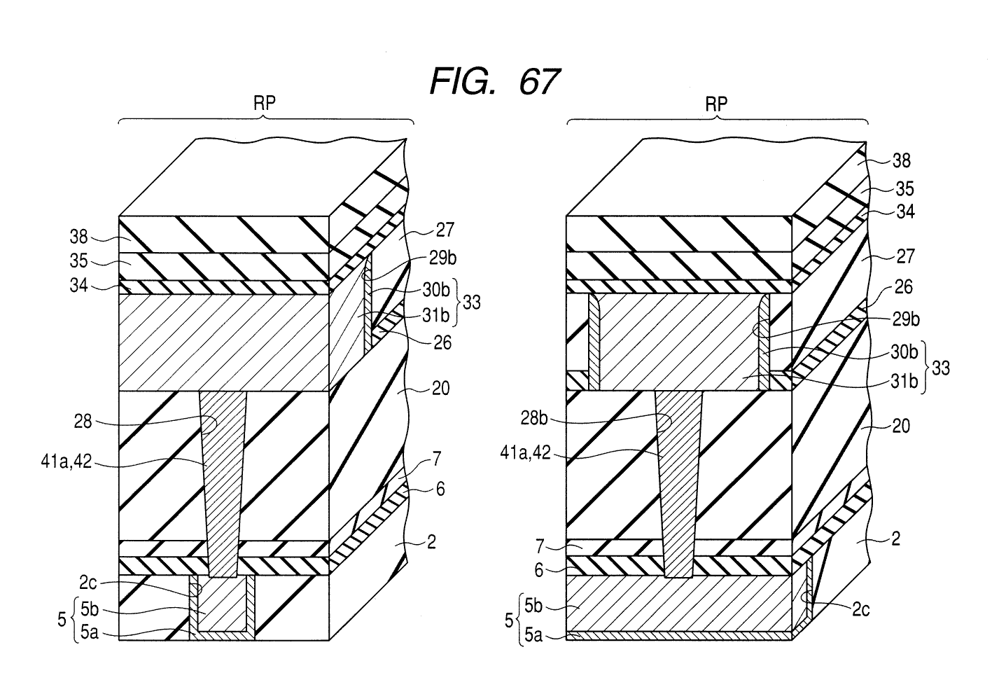

Next, by subjecting the copper film 31 to a chemical mechanical polishing treatment, as shown in FIGS. 66 and 67, in the memory cell region RM, the bit line 32 constituted by the cladding layer 30a and the copper film 31a is formed in the wiring trench 29a, and, in the peripheral circuitry region RP, the bit line 33 constituted by the cladding layer 30b and the copper film 31b is formed in the wiring trench 29b.

Next, in the memory cell region RM, the cladding layer 36a covering the bit line 32 is formed over the bit line 32 via the silicon nitride film 34. After that, the silicon oxide film 37a is formed so as to cover the cladding layer 36a, and, furthermore, the silicon oxide film 38 is formed. In the peripheral circuitry region RP, the bit line 33 constituted by the cladding layer 30b and the copper film 31b is formed in the wiring trench 29b. Over the bit line 33, the silicon oxide film 35 is formed via the silicon nitride film 34, and, furthermore, the silicon oxide film 38 is formed. Thus, the maim portion of the semiconductor device is formed.

In the aforementioned semiconductor device, as described already, the top via 25a does not include the cladding layer, and, therefore, the deterioration of the rewrite property may be suppressed. Moreover, since the peripheral circuitry via hole 28b in the peripheral circuitry region RP is formed after the formation of the top via 25a in the memory cell region RM, it is possible to individually optimize the etching condition for forming the top via hole 21 in the memory cell region RM, and the etching condition for forming the peripheral circuitry via hole 28b in the peripheral circuitry region RP.

This makes it possible to electrically couple the bit line 32 and the magnetoresistive element 18 without causing damage to the magnetoresistive element 18 in the memory cell region RM, and to surely electrically couple the bit line 33 and the wiring 5 in the peripheral circuitry region RP. Further, the peripheral circuitry via 41a formed in the peripheral circuitry via hole 28b in the peripheral circuitry region RP is formed from a copper film, and thus the resistance as a via may also be lowered.

### Example 4

Here, particularly, a semiconductor device, in which the cladding layer is formed in the peripheral circuitry via hole in the peripheral circuitry region and a peripheral circuitry via including the cladding layer is provided as a peripheral circuitry via, is explained.

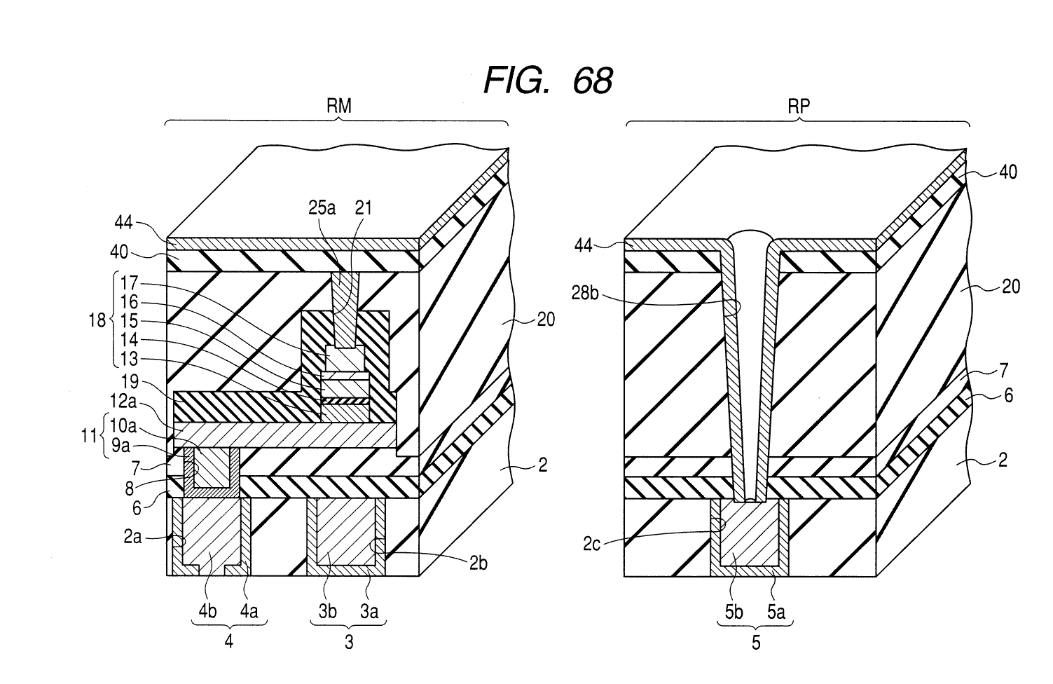

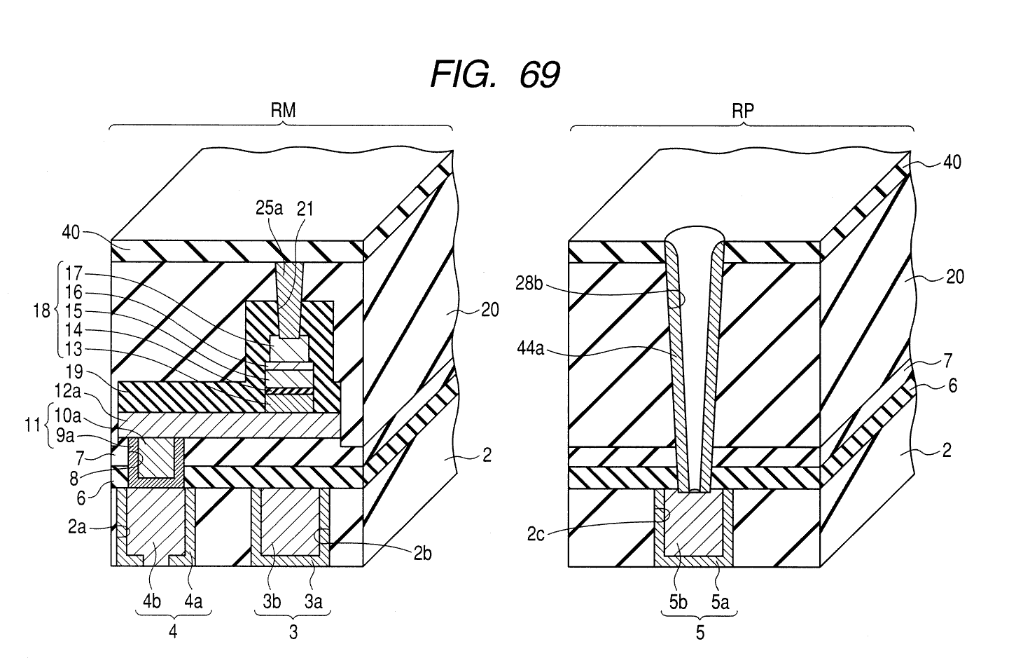

After the aforementioned processes shown in FIGS. 60 and 61, a cladding layer 44 is formed so as to cover the silicon nitride film 40 in the memory cell region RM, and to cover the side wall and the like of the peripheral circuitry via hole 28b in the peripheral circuitry region RP as shown in FIG. 68. Next, the whole surface of the cladding layer 44 is etched to remove the cladding layer 44 lying over the upper surface of the silicon nitride film 40 in the memory cell region RM, as shown in FIG. 69. In the peripheral circuitry region RP, the portion of the cladding layer 44 lying over the upper surface of the silicon nitride film 40 and the portion of the cladding layer 44 lying at the bottom of the peripheral circuitry via hole 28b are removed, while the portion of the cladding layer 44 lying over the side wall of the peripheral circuitry via hole 28b (a cladding layer 44a) is left.

Meanwhile, at this time, the cladding layer 44 may be removed in a mode that leaves a part of the barrier metal film in the cladding layer 44 lying over the bottom surface of the peripheral circuitry via hole 28b, and a part of the barrier metal film in the cladding layer 44 lying over the upper surface of the silicon nitride film 40. Further, after that, a barrier metal film (not shown) may be formed so as to cover the peripheral circuitry via hole 28b and the silicon nitride film 40.

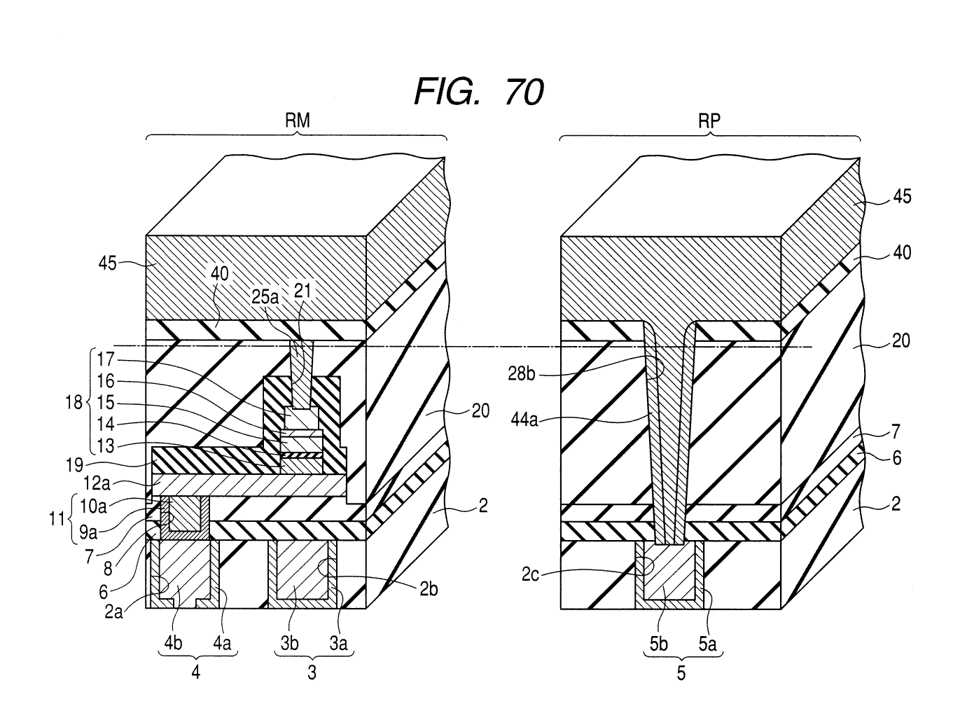

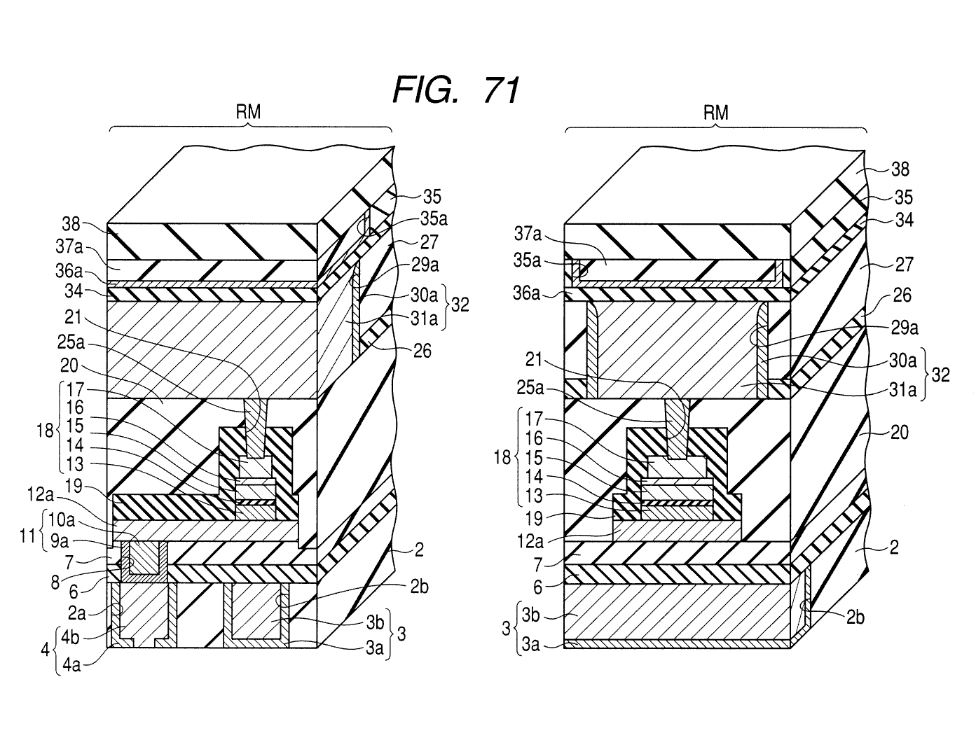

Next, as shown in FIG. 70, a copper film 45 is formed by copper plating over the silicon nitride film 40 so as to fill up the peripheral circuitry via hole 28b. Next, by subjecting the copper film 45 to a chemical mechanical polishing treatment, the portion of the copper film 45 lying over the upper surface of the silicon nitride film 40 is removed, and, furthermore, the silicon nitride film 40 and a part of the silicon oxide film 20 are removed (see the position of dashed one-dotted line). Thus, in the peripheral circuitry via hole 28b, the peripheral circuitry via 46 constituted by the cladding layer 44a and the copper film 45a is formed (see FIG. 72).

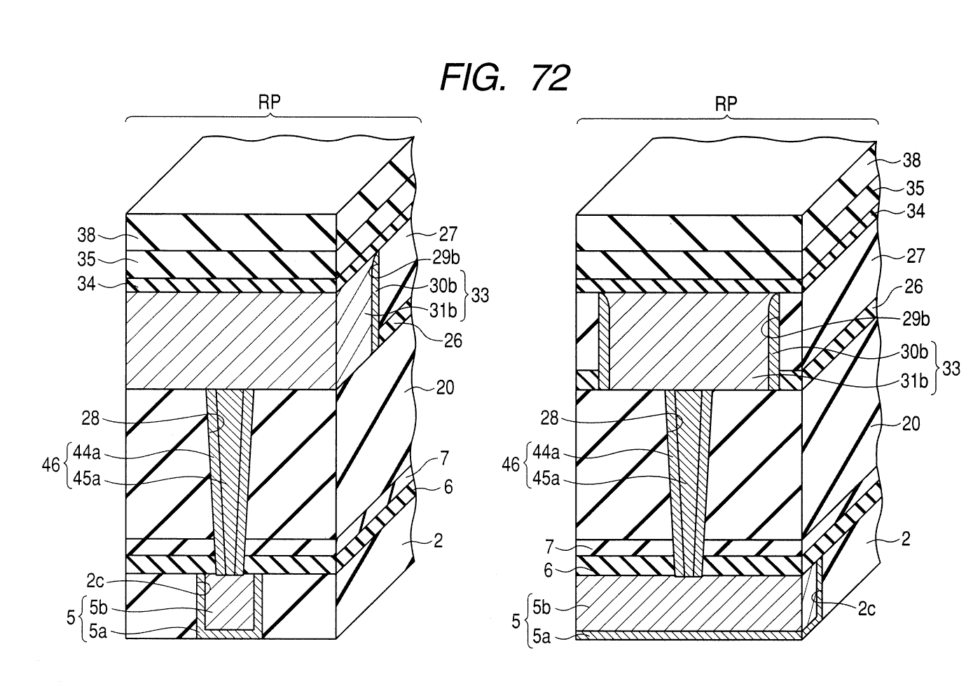

Next, by going through the same processes as those shown in FIGS. 63 to 67, in the memory cell region RM, the bit line 32 is formed in the wiring trench 29a, and, over the bit line 32, the cladding layer 36a covering the bit line 32 via the silicon nitride film 34 is formed as shown in FIG. 71. After that, the silicon oxide film 37a is formed so as to cover the cladding layer 36a, and, furthermore, the silicon oxide film 38 is formed.

In addition, as shown in FIG. 72, in the peripheral circuitry region RP, the bit line 33 is formed in the wiring trench 29b. Over the bit line 33, the silicon oxide film 35 is formed via the silicon nitride film 34, and, furthermore, the silicon oxide film 38 is formed. Thus, the main portion of the semiconductor device is formed.

In the aforementioned semiconductor device, as explained already, since the top via 25a does not include the cladding layer, the deterioration of the rewrite property may be suppressed. Moreover, since the peripheral circuitry via hole 28b in the peripheral circuitry region RP is formed after the formation of the top via 25a in the memory cell region RM, the etching condition for forming the top via hole 21 in the memory cell region RM, and the etching condition for forming the peripheral circuitry via hole 28b in the peripheral circuitry region RP may be optimized individually.

This makes it possible to electrically couple the bit line 32 and the magnetoresistive element 18 without causing damage to the magnetoresistive element 18 in the memory cell region RM, and to surely electrically couple the bit line 33 and the wiring 5 in the peripheral circuitry region RP.

Furthermore, in the peripheral circuitry via hole 28b in the peripheral circuitry region RP, the peripheral circuitry via 46 constituted by the copper film 45a and the cladding layer 44a is formed. This makes it possible to prevent the magnetic field generated by the current flowing through the peripheral circuitry via 46 from leaking to the outside of the peripheral circuitry via hole 28b by the cladding layer 44a, and to suppress the influence of the magnetic field on the magnetoresistive element 18.

The above-described respective Examples are explained while taking a NiFe layer as the example of the cladding layer having such a function as shielding the magnetic field, but, as the material of the cladding layer, soft magnetic materials give the intended effect of shielding the magnetic field. The soft magnetic material is a material having a small coercive force and a large magnetic permeability. The NiFe layer is an example, and is referred to as Permalloy (an alloy of Ni and Fe). As the soft magnetic material, there are such a material obtained by adding Mo, Cu, Cr or the like to Permalloy, soft ferrite (AFe₂O₄ (A=Mn, Co, Ni, Cu, Zn, Fe or the like)), AFe₁₂O₁₉ (A=Ba, Sr, Pb or the like), RFe₅O₁₂ (R=a rare-earth element)), iron, silicon steel, Sendust, permendur and an amorphous magnetic alloy (a Fe—Si—B compound), in addition to Permalloy.

Further, the above-described respective Examples are explained while taking a top via made from a copper film as the example of the top via, but, as the material of the top via, any non-magnetic material may apply the magnetic field generated by the current flowing through the bit line on the magnetoresistive element without being affected by the top via. The non-magnetic material is a material other than the material that shows the magnetic property, and materials other than soft magnetic materials and hard magnetic materials may be applied as the material of the top via. Meanwhile, the hard magnetic material is a material having a large coercive force including alnico (Al—Ni—Co)-based materials, hard ferrite (BaCO₃, StCO₃), samarium cobalt (SmCo₅, Sm₂Co₁₇)-based materials, and neodymium (Nd₂Fe₁₄B)-based materials.

Furthermore, the material of the wiring main body of the bit line and the like is explained while taking a copper film as the example, but, as the material of the wiring main body, for example, AlSi, AlSiCu, TiN/AlSi, AlCu, Ag, Au or the like may be applied, in addition to copper.

Examples disclosed this time are those for exemplification, and the present invention is not limited to these. It is shown by the claim, not by the range as explained above, and, all the changes in the meaning and range that are equivalent to the claim are intended to be included.

The present invention is effectively utilized for semiconductor devices provided with the magnetoresistive element.

What is claimed is:

1. A semiconductor device comprising:
a first region formed in a main surface of a semiconductor substrate;
a magnetoresistive element formed in the first region;
a first wiring main body formed so as to extend in a first direction directly under the magnetoresistive element with some spacing;
a second wiring main body formed so as to extend in a second direction intersecting the first direction directly on the magnetoresistive element with some spacing;
a first conductor portion that is formed between the magnetoresistive element and the second wiring main body and electrically couples the magnetoresistive element and the second wiring main body; and
a magnetic field-shielding layer that is formed in a prescribed position relative to the magnetoresistive element and shields a magnetic field generated by a current flowing through the first wiring main body and the second wiring main body,
wherein the first conductor portion is formed from a non-magnetic material, and the magnetic field-shielding layer is formed over the surface of the second wiring main body in a mode that excludes a portion of the second wiring main body facing the magnetoresistive element and the first conductor portion.

2. The semiconductor device according to claim 1 comprising:
a second region that is formed in the main surface of the semiconductor substrate, in which the second wiring main body extends;
a third wiring main body that is formed below the second wiring main body with some spacing in the second region; and
a second conductor portion that is formed between the third wiring main body and a portion of the second wiring main body lying in the second region and electrically couples the third wiring main body and the second wiring main body.

3. The semiconductor device according to claim 2,
wherein the magnetic field-shielding layer is furthermore formed over the surface of the second conductor portion.

4. The semiconductor device according to claim 2,
wherein the magnetic field-shielding layer is formed over the surface of the second wiring main body in a mode that excludes the second conductor portion.

5. The semiconductor device according to claim 1,
wherein the magnetic field-shielding layer is formed from a soft magnetic material.

6. A method of manufacturing a semiconductor device having a first region and a second region in a main surface of a semiconductor substrate comprising the steps of:
forming a first insulating film over the main surface of the semiconductor substrate;
forming a first wiring trench extending in a first direction in the first insulating film;
forming a first wiring main body in the first wiring trench;
forming a second insulating film over the first insulating film so as to cover the first wiring main body;
forming a magnetoresistive element over the surface of the second insulating film;
forming a third insulating film over the second insulating film so as to cover the magnetoresistive element;
forming a first opening to expose the magnetoresistive element in the third insulating film;
forming a first electroconductive film constituted by a non-magnetic material over the third insulating film so as to fill up the first opening;
removing a portion of the first electroconductive film lying over the upper surface of the third insulating film to form a first conductor portion electrically coupled to the magnetoresistive element by a portion of the first electroconductive film left in the first opening;
forming a fourth insulating film over the third insulating film so as to cover the first conductor portion;
forming a second wiring trench extending in a second direction intersecting the first direction in the fourth insulating film so that the first conductor portion is exposed at the bottom surface;
forming a magnetic field-shielding layer that shields a magnetic field over the side wall of the second wiring trench in a mode that excludes the bottom surface of the second wiring trench; and
forming a second wiring main body electrically coupled to the magnetoresistive element via the first conductor portion in the second wiring trench.

7. The method of manufacturing a semiconductor device according to claim 6 comprising the steps of:
forming a third wiring trench in a portion of the first insulating film lying in the second region;
forming a third wiring main body in the third wiring trench; and
forming a second conductor portion that passes through the second insulating film and the third insulating film to electrically couple the third wiring main body and a portion of the first wiring main body lying in the second region.

8. The method of manufacturing a semiconductor device according to claim 7,
wherein the step of forming the second conductor portion includes the steps of:
forming, after the formation of the fourth insulating film and prior to the formation of the second wiring trench, a second opening that passes through the second insulating film, the third insulating film and the fourth insulating film to expose the third wiring main body in the second region;
forming the second wiring trench in the fourth insulating film so as to expose the second opening at the bottom surface;
forming a layer to be a magnetic field-shielding layer so as to cover the bottom surface and the side surface of the second wiring trench, and the side wall of the second opening;
subjecting the whole surface of the layer to be the magnetic field-shielding layer to etching to remove a portion lying at the bottom surface of the second wiring trench, while leaving a portion lying over the side wall of the second wiring trench and a portion lying over the side wall of the second opening; and
forming a portion of a layer to be the magnetic field-shielding layer and a portion of the second electroconductive film each lying in the second opening as the second conductor portion, by filling up the second opening with the second electroconductive film to be the second wiring main body when forming the second wiring main body.

9. The method of manufacturing a semiconductor device according to claim 7,
wherein the step of forming the second conductor portion includes the steps of:
forming, after the formation of the third insulating film, a second opening that passes through the third insulating film and the second insulating film to expose the third wiring main body;
forming a third electroconductive film over the third insulating film so as to fill up the second opening; and
removing a portion of the third electroconductive film lying over the upper surface of the third insulating film to form a portion of the third electroconductive film left in the second opening as the second conductor portion.

10. The method of manufacturing a semiconductor device according to claim 7,
wherein the step of forming the second conductor portion includes the steps of:
forming, after the formation of the third insulating film, a second opening that passes through the third insulating film and the second insulating film to expose the third wiring main body;
forming a layer to be a magnetic field-shielding layer over the third insulating film so as to cover the side wall of the second opening;
removing a portion of the layer to be the magnetic field-shielding layer lying over the upper surface of the third insulating film, while leaving a portion of the layer to be the magnetic field-shielding layer lying over the side wall of the second opening;
forming a fourth electroconductive film over the third insulating film so as to fill up the second opening; and
removing a portion of the fourth electroconductive film lying over the upper surface of the third insulating film to form a portion of the layer to be the magnetic field-shielding layer and a portion of the fourth electroconductive film each left in the second opening as the second conductor portion.
